(19) United States
(12) Patent Application Publication
(10) Pub. No.: US 2026/0072475 A1
(43) Pub. Date: Mar. 12, 2026

(54) DISPLAY DEVICE AND ELECTRONIC APPARATUS INCLUDING THE DISPLAY DEVICE

(71) Applicant: Samsung Display Co., Ltd., Yongin-si (KR)

(72) Inventor: JONGHWAN CHO, Yongin-si (KR)

(21) Appl. No.: 19/305,923

(22) Filed: Aug. 21, 2025

(30) Foreign Application Priority Data
Sep. 12, 2024 (KR) 10-2024-0124728
Apr. 7, 2025 (KR) 10-2025-0044620

(51) Int. Cl. G06F 1/16; G02B 1/111; G02B 1/14; H10H 29/855; H10K 59/80

(52) U.S. Cl. CPC G06F 1/1656; G02B 1/111; G02B 1/14; G06F 1/1641; H10H 29/855; H10K 59/879

(57) ABSTRACT

A display device may include a display panel foldable based on at least one folding axis, and a protective member disposed on the display panel. The protective member may include a base layer, a hard coating layer disposed on the base layer, a first low refractive index layer disposed on the hard coating layer, and a primer layer disposed between the hard coating layer and the first low refractive index layer. The primer layer may include a metal compound and a polar compound, the metal compound may include a titanium alkoxide oligomer, a zirconium alkoxide oligomer, or a zirconium chelate compound, and a number of carbon atoms included in the titanium alkoxide oligomer may be 96 to 320. Accordingly, the display device may show excellent display quality and excellent folding reliability.

### CROSS-REFERENCE TO RELATED APPLICATIONS

This U.S. non-provisional patent application claims priority to Korean Patent Application Nos. 10-2024-0124728, filed on Sep. 12, 2024, and 10-2025-0044620, filed on Apr. 7, 2025, and all the benefits accruing therefrom under 35 U.S.C. § 119, the entire contents of which are hereby incorporated by reference.

### BACKGROUND

The present disclosure herein relates to a foldable display device and an electronic apparatus including the display device.

Various electronic apparatuses such as televisions, mobile phones, tablet computers, and game consoles are being developed. Recently, flexible electronic apparatuses including flexible display panels capable of folding, rolling or sliding have been developed. Unlike rigid electronic apparatuses, flexible electronic apparatuses may be folded or rolled. Flexible electronic apparatuses, having shapes that may be changed in various ways, may be folded and carried regardless of the existing screen size, thereby improving user convenience. Flexible electronic apparatuses require that various parts of the apparatuses maintain their flexible operation reliability.

### SUMMARY

The present disclosure provides a display device exhibiting excellent display qualities and excellent folding reliability and an electronic apparatus including the display device.

An embodiment provides a display device including a display panel foldable based on at least one folding axis, and a protective member disposed on the display panel, wherein the protective member includes a base layer, a hard coating layer disposed on the base layer, a first low refractive index layer disposed on the hard coating layer, and a primer layer including a metal compound and a polar compound, and disposed between the hard coating layer and the first low refractive index layer, the metal compound includes at least of a titanium alkoxide oligomer, a zirconium alkoxide oligomer, or a zirconium chelate compound, wherein a number of carbon atoms included in the titanium alkoxide oligomer is 96 to 320.

In an embodiment, the titanium alkoxide oligomer may include at least one of a first moiety represented by Formula 1 below or a second moiety represented by Formula 2 below, the zirconium alkoxide oligomer may include at least one of a third moiety represented by Formula 3 below or a fourth moiety represented by Formula 4 below, and the zirconium chelate compound may include zirconium acetylacetonate.

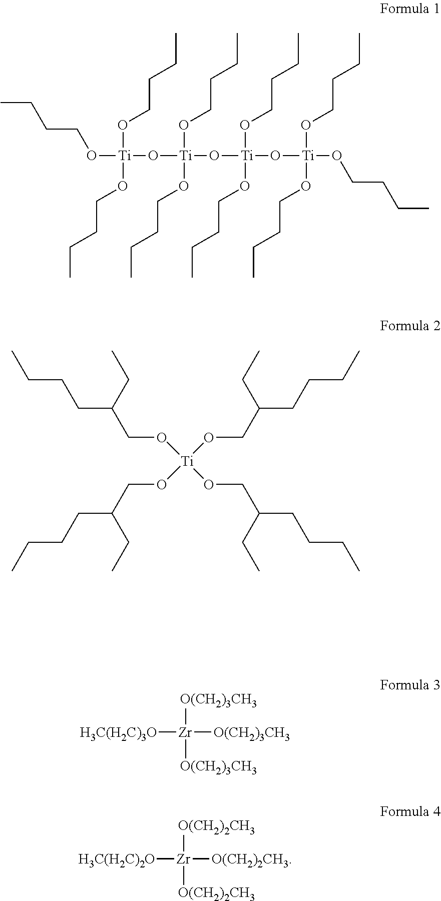

In an embodiment, the polar compound may include an amine group.

In an embodiment, the polar compound may include at least one of 2-(2-aminoethoxy)ethylamine, 4-(2-aminoethoxy)phenol, or triethanolamine.

In an embodiment, a refractive index of the primer layer may be higher than a refractive index of the first low refractive index layer.

In an embodiment, a refractive index of the primer layer may be about 1.62 to about 1.91.

In an embodiment, a thickness of the primer layer may be smaller than a thickness of the hard coating layer.

In an embodiment, the primer layer may be disposed directly between the hard coating layer and the first low refractive index layer.

In an embodiment, the first low refractive index layer may include at least one of silicon dioxide (SiO₂) or a first substitutional solid liquid, and the first substitutional solid liquid may include silicon atoms, aluminum atoms, and oxygen atoms.

In an embodiment, the protective member may further include a high refractive index layer disposed on the first low refractive index layer, and a second low refractive index layer disposed on the high refractive index layer.

In an embodiment, the high refractive index layer may include a second substitutional solid solution including niobium atoms, titanium atoms, and oxygen atoms, and the second low refractive index layer may include silicon dioxide.

In an embodiment, the hard coating layer may include a silsesquioxane resin.

In an embodiment, the silsesquioxane resin may include at least one of a random structure, a partial cage structure, a ladder structure or a cage structure.

In an embodiment, the base layer may include at least one among polyethylene terephthalate, polyimide, polyacrylate, polymethyl acrylate, polymethyl methacrylate, polycarbonate, polyethylene naphthalate, polyvinylidene chloride, polyvinylidene difluoride, polystyrene, and an ethylene vinyl alcohol copolymer.

An embodiment provides an electronic apparatus providing images, wherein the display device includes a display panel foldable based on at least one folding axis, and a protective member disposed on the display panel, the protective member includes a base layer, a hard coating layer disposed on the base layer, a first low refractive index layer disposed on the hard coating layer, and a primer layer including a metal compound and a polar compound, and disposed between the hard coating layer and the first low refractive index layer, the metal compound includes at least one of a titanium alkoxide oligomer, a zirconium alkoxide oligomer, or a zirconium chelate compound, wherein a number of carbon atoms included in the titanium alkoxide oligomer is 96 to 320.

In an embodiment, the titanium alkoxide oligomer may include at least one of a first moiety represented by Formula 1 above or a second moiety represented by Formula 2 above, the zirconium alkoxide oligomer may include at least one of a third moiety represented by Formula 3 above or a fourth moiety represented by Formula 4 above, and the zirconium chelate compound may include zirconium acetylacetonate.

In an embodiment, the polar compound may include at least one of 2-(2-aminoethoxy)ethylamine, 4-(2-aminoethoxy)phenol, or triethanolamine.

In an embodiment, a refractive index of the primer layer may be higher than a refractive index of the first low refractive index layer, and a refractive index of the primer layer may be about 1.62 to about 1.91.

In an embodiment, the protective member may further include a high refractive index layer disposed on the first low refractive index layer, and a second low refractive index layer disposed on the high refractive index layer, and the high refractive index layer may include a substitutional solid solution including niobium atoms, titanium atoms, and oxygen atoms.

In one or more embodiments, the electronic apparatus may further include a processor, a power module, or a memory.

### BRIEF DESCRIPTION OF THE FIGURES

The accompanying drawings are included to provide a further understanding of the display device and electronic apparatus are incorporated in and constitute a part of this specification. The drawings illustrate embodiments of the display device and electronic apparatus and, together with the description, serve to explain principles of the display device and electronic apparatus. In the drawings:

FIG. 1A is a perspective view showing an electronic apparatus of an embodiment;

FIG. 1B is a perspective view showing an electronic apparatus of an embodiment;

FIG. 1C is a plan view showing an electronic apparatus of an embodiment;

FIG. 1D is a perspective view showing an electronic apparatus of an embodiment;

FIG. 2A is a perspective view showing an electronic apparatus of an embodiment;

FIG. 2B is a perspective view showing an electronic apparatus of an embodiment;

FIG. 2C is a perspective view showing an electronic apparatus of an embodiment;

FIG. 3 is an exploded perspective view showing an electronic apparatus of an embodiment;

FIG. 4 is a cross-sectional view showing a portion corresponding to line I-I′ in FIG. 3;

FIG. 5 is an enlarged cross-sectional view showing an area XX′ in FIG. 4;

FIG. 6A is an enlarged cross-sectional view showing an area YY′ in FIG. 5;

FIG. 6B is a cross-sectional view showing a portion of an electronic apparatus of an embodiment;

FIG. 7 is a cross-sectional view showing a portion of an electronic apparatus of an embodiment;

FIG. 8 is a diagram showing a material included in a primer layer;

FIG. 9 is a cross-sectional view showing a portion corresponding to line II-II′ in FIG. 3;

FIG. 10 is a block diagram of an electronic apparatus according to an embodiment; and

FIG. 11 illustrates schematic diagrams of electronic apparatuses according to various embodiments.

### DETAILED DESCRIPTION

The embodiments of the description may have various modifications and may be embodied in different forms, and example embodiments will be explained in detail with reference to the accompanying drawings. The embodiments of the description may, however, be embodied in different forms and should not be construed as limited to the embodiments set forth herein. Rather, all modifications, equivalents, and substituents which are included in the spirit and technical scope of the embodiments of the description should be included.

In the description, when an element (or a region, a layer, a part, or the like) is referred to as being “on,” “connected with” or “combined with” another element, it can be directly disposed on/connected with/bonded to the other element, or intervening third elements may also be disposed the elements.

Like reference numerals refer to like elements throughout. In the drawings, the thicknesses, ratios, and dimensions of elements are exaggerated for effective explanation of technical contents. The term “and/or” may include one or more combinations that may define relevant elements.

It will be understood that, although the terms first, second, or the like may be used herein to describe various elements, these elements should not be limited by these terms. These terms are only used to distinguish one element from another element. For example, a first element could be termed a second element without departing from the scope of the description of the embodiments herein. Similarly, a second element could be termed a first element. As used herein, the singular forms are intended to include the plural forms as well, unless the context clearly indicates otherwise. Thus, reference to “an embodiment” is inclusive of one or more embodiments.

In addition, the terms “below”, “beneath”, “on” and “above” are used for explaining the relation of elements shown in the drawings. The terms are relative concepts and are explained based on the direction shown in the drawing.

It will be further understood that the terms “comprises” or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this description belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly defined so herein.

In the description, an alkyl group may be linear, branched, or cyclic. The number of carbon atoms in the alkyl group may be 1 to 60, 1 to 50, 1 to 30, 1 to 20, 1 to 10, or 1 to 6, unless otherwise specified. Examples of alkyl group may include a methyl group, an ethyl group, a n-propyl group, an isopropyl group, a cyclopropyl group, a n-butyl group, a s-butyl group, a t-butyl group, an i-butyl group, a 2-ethylbutyl group, a 3,3-dimethylbutyl group, a cyclobutyl group, a n-pentyl group, an i-pentyl group, a neopentyl group, a t-pentyl group, a 1-methylpentyl group, a 3-methylpentyl group, a 2-ethylpentyl group, a 4-methyl-2-pentyl group, a cyclopentyl group, a n-hexyl group, a 1-methylhexyl group, a 2-ethylhexyl group, a 2-butylhexyl group, a cyclohexyl group, a 4-methylcyclohexyl group, a 4-butylcyclohexyl group, a n-heptyl group, a 1-methylheptyl group, a 2,2-dimethylheptyl group, a 2-ethylheptyl group, a 2-butylheptyl group, a cycloheptyl group, a bicycloheptyl group, a n-octyl group, a t-octyl group, a 2-ethyloctyl group, a 2-butyloctyl group, a 2-hexyloctyl group, a 3,7-dimethyloctyl group, a cyclooctyl group, a n-nonyl group, a cyclononyl group, a n-decyl group, a cyclodecyl group, a norbornyl group, a 1-adamantyl group, a 2-adamantyl group, an isobornyl group, a 2-ethyldecyl group, a 2-butyldecyl group, a 2-hexyldecyl group, a 2-octyldecyl group, a n-undecyl group, a n-dodecyl group, a 2-ethyldodecyl group, a 2-butyldodecyl group, a 2-hexyldodecyl group, a 2-octyldodecyl group, a n-tridecyl group, a n-tetradecyl group, a n-pentadecyl group, a n-hexadecyl group, a 2-ethylhexadecyl group, a 2-butylhexadecyl group, a 2-hexylhexadecyl group, a 2-octylhexadecyl group, a n-heptadecyl group, a n-octadecyl group, a n-nonadecyl group, a n-icosyl group, a 2-ethylicosyl group, a 2-butylicosyl group, a 2-hexylicosyl group, a 2-octylicosyl group, a n-henicosyl group, a n-docosyl group, a n-tricosyl group, a n-tetracosyl group, a n-pentacosyl group, a n-hexacosyl group, a n-heptacosyl group, a n-octacosyl group, a n-nonacosyl group, and a n-triacontyl group, but are not limited thereto.

In the description, an alkenyl group means a hydrocarbon group including one or more carbon double bonds in the middle or terminal end of an alkyl group having 2 or more carbon atoms. The alkenyl group may be linear or branched. The number of carbon atoms in the alkenyl group is not particularly limited, but may be 2 to 60, 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, or the like, but are not limited thereto.

In the description, an aryl group means any functional group or substituent derived from an aromatic hydrocarbon ring. The aryl group may be a monocyclic aryl group or a polycyclic aryl group. The number of ring-forming carbon atoms of the aryl group may be 6 to 60, 6 to 30, 6 to 20, or 6 to 15. Examples of aryl group include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, and a chrysenyl group, but are not limited thereto.

In the description, an alkoxy group may mean an alkyl group defined above to which an oxygen atom is bonded. The alkoxy group may be linear, branched, or cyclic. The number of carbon atoms of the alkoxy group is not particularly limited, but may be, for example, 1 to 60, 1 to 30, 1 to 20, or 1 to 10. Examples of alkoxy group include methoxy, ethoxy, n-propoxy, isopropoxy, butoxy, pentyloxy, hexyloxy, octyloxy, nonyloxy, and decyloxy, but are not limited thereto.

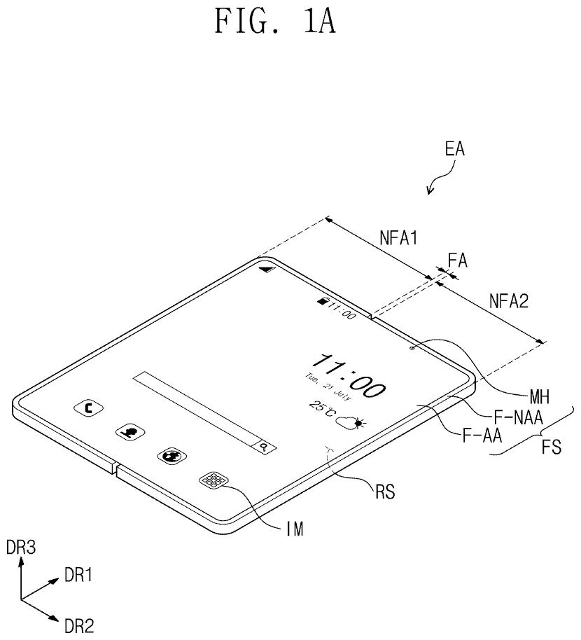

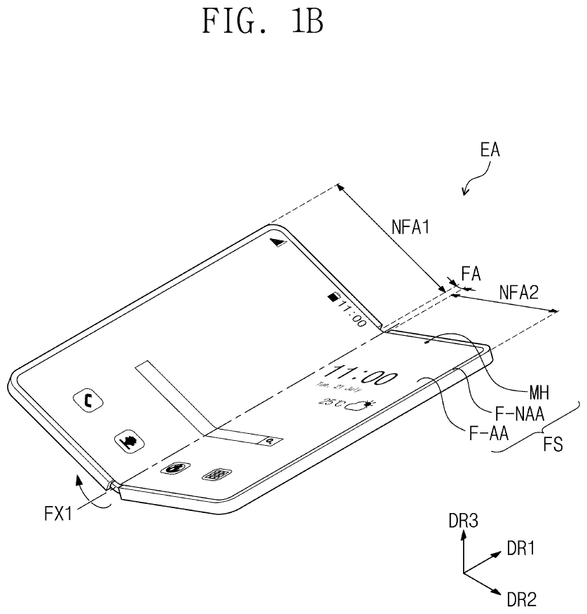

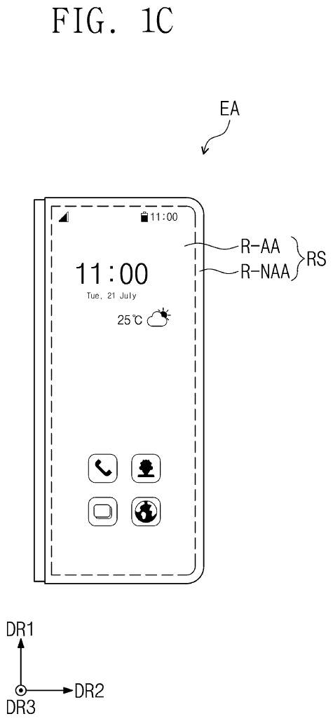

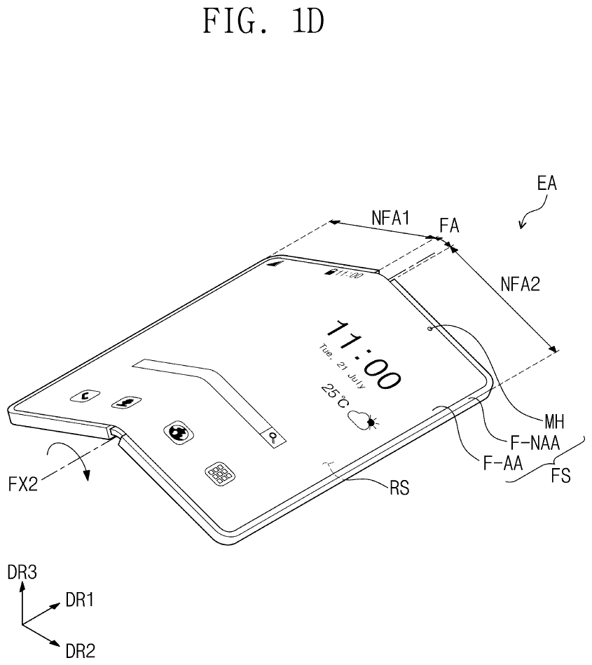

Hereinafter, a display device and an electronic apparatus including the display device according to an embodiment of the disclosure will be described with reference to the drawings. FIG. 1A is a perspective view of an electronic apparatus EA in an unfolded state according to an embodiment.

An electronic apparatus EA of an embodiment may be an apparatus activated according to an electrical signal. For example, the electronic apparatus EA may be a smartphone, a tablet, a car navigation system, a game console, or a wearable apparatus, but embodiments of the inventive concept is not limited thereto. In FIG. 1A and the like, the electronic apparatus EA is illustrated as a smartphone.

The electronic apparatus EA may include a first display surface FS defined by a first direction axis DR1 and a second direction axis DR2 crossing the first direction axis DR1. The electronic apparatus EA may provide an image IM to a user through the first display surface FS. The electronic apparatus EA may display an image IM toward a third direction axis DR3 to the first display surface FS that is parallel to each of the first direction axis DR1 and the second direction axis DR2. The image IM may include a dynamic image and a static image.

In the description, the first direction axis DR1 and the second direction axis DR2 may be orthogonal to each other, and the third direction axis DR3 may be a normal direction to a plane defined by the first direction axis DR1 and the second direction axis DR2. The thickness direction of the electronic apparatus EA may be a direction parallel to the third direction axis DR3. The thickness direction of the electronic apparatus EA may use the same drawing symbol as the third direction axis DR3. The front (or upper surface) and the back (or lower surface) are opposite to each other in the third direction axis DR3, and the normal direction of each of the front (or upper surface) and the back (or lower surface) may be parallel to the third direction axis DR3. The front (or upper surface) refers to a surface adjacent to the first display surface FS, and the back (or lower surface) refers to a surface spaced from the first display surface FS. In addition, the back (or lower surface) refers to a surface close to a second display surface RS described later. The upper side refers to a direction approaching the first display surface FS, and the lower side refers to a direction away from the first display surface FS.

A cross-section refers to a surface parallel to the thickness direction DR3, and a plane refers to a surface perpendicular to the thickness direction DR3. The plane refers to a plane parallel to a plane defined by the first direction axis DR1 and the second direction axis DR2.

The directions indicated by the first to third direction axes DR1, DR2 and DR3 described in the description are relative concepts and may be converted into other directions. In addition, the directions indicated by the first to third direction axes DR1, DR2 and DR3 may be described as the first to third directions, and the same drawing symbols may be used.

The electronic apparatus EA may detect external inputs applied from the outside. The external inputs may include various types of inputs provided from the outside of the electronic apparatus EA. For example, the external inputs may include contact by a part of the body such as a user's hand, as well as external inputs (for example, hovering) applied in proximity to the electronic apparatus EA or at a predetermined distance. In addition, the external inputs may have various forms such as force, pressure, temperature and light.

The electronic apparatus EA may include a first display surface FS and a second display surface RS. The first display surface FS may include a first active area F-AA, a first peripheral area F-NAA, and a sub-area MH. The second display surface RS may be defined as a surface facing at least a portion of the first display surface FS. That is, the second display surface RS may be defined as a portion of the rear surface of the electronic apparatus EA.

The first active area F-AA may be an area activated according to an electrical signal. The first active area F-AA may be an area where an image IM is displayed and various types of external inputs may be detected.

The first peripheral area F-NAA may be adjacent to the first active area F-AA. The light transmittance of the first peripheral area F-NAA may be lower than the light transmittance of the first active area F-AA. The first peripheral area F-NAA may have a predetermined color. The first peripheral area F-NAA may surround the first active area F-AA. Accordingly, the shape of the first active area F-AA may be substantially defined by the first peripheral area F-NAA. However, this is an illustration, and the first peripheral area F-NAA may be disposed adjacent to only one side of the first active area F-AA or may be omitted.

The sub-area MH may detect an external subject received through the display surfaces FS and RS or provide a sound signal such as a voice to the outside through the display surfaces FS and RS. An optical signal such as visible light and infrared light may move to the sub-area MH.

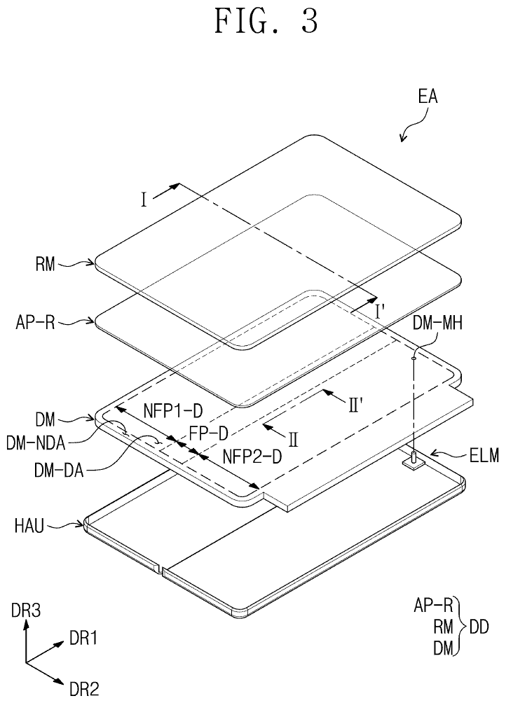

Various electronic modules ELM (FIG. 3) may be disposed to correspond to the sub-area MH. For example, the electronic module ELM (FIG. 3) may include at least one of a camera, a speaker, a light detection sensor, or a heat detection sensor. The electronic apparatus EA may include an electronic module ELM (FIG. 3) that captures an external image through visible light passing through the sub-area MH or determines the accessibility of an external object through infrared light. The electronic module ELM (FIG. 3) may include multiple configurations and is not limited to any one embodiment.

The sub-area MH may be disposed within the first active area F-AA. However, this is an illustrative embodiment and does not limit the disclosure. For example, the sub-area MH may be surrounded by the first peripheral area F-NAA, or the sub-area MH may be surrounded by the first active area F-AA and the first peripheral area F-NAA. Although one sub-area MH is illustrated in FIG. 1A, multiple sub-areas MH may be provided.

The electronic apparatus EA of an embodiment may include at least one folding area FA and multiple non-folding areas NFA1 and NFA2, extended from the folding area FA. For example, a first non-folding area NFA1, a folding area FA, and a second non-folding area NFA2 may be defined along the second direction DR2. The electronic apparatus EA of an embodiment may include a first non-folding area NFA1 and a second non-folding area NFA2 spaced apart from each other in the second direction DR2 with the folding area FA interposed therebetween. For example, the first non-folding area NFA1 may be disposed on one side of the folding area FA along the second direction DR2, and the second non-folding area NFA2 may be disposed on the other side of the folding area FA along the second direction DR2.

Although the illustrated embodiment of an electronic apparatus EA depicted in FIG. 1A includes one folding area FA, embodiments of the electronic apparatus are not limited thereto, and multiple folding areas may be defined in the electronic apparatus EA. For example, the electronic apparatus according to an embodiment may include two or more folding areas, and may also include three or more non-folding areas disposed with each of the folding areas interposed therebetween.

FIG. 1B is a perspective view showing a folding operation of an electronic apparatus EA according to an embodiment. FIG. 1C is a plan view showing a folded state of an electronic apparatus EA according to an embodiment. FIG. 1D is a perspective view showing a folding operation of an electronic apparatus EA according to an embodiment.

Referring to FIG. 1B, the electronic apparatus EA according to an embodiment may be folded based on the first folding axis FX1 extended in the first direction DR1. In a folded state of the electronic apparatus EA, the folding area FA may have a predetermined curvature and radius of curvature. The electronic apparatus EA may be folded based on the first folding axis FX1 so that the first non-folding area NFA1 and the second non-folding area NFA2 face each other and may be transformed into an in-folding state so that the first display surface FS is not exposed to the outside.

FIG. 1C is a plan view showing the electronic apparatus EA in an in-folded state. Referring to FIG. 1C, in the electronic apparatus EA according to an embodiment, the second display surface RS may be visible to a user in an in-folded state. In this case, the second display surface RS may include a second active area R-AA that displays an image. The second active area R-AA may be an area activated according to an electrical signal. The second active area R-AA may be an area where an image is displayed, and various types of external inputs may be detected.

The second peripheral area R-NAA may be adjacent to the second active area R-AA. The light transmittance of the second peripheral area R-NAA may be lower than the light transmittance of the second active area R-AA. The second peripheral area R-NAA may have a predetermined color. The second peripheral area R-NAA may surround the second active area R-AA. Although not illustrated, the electronic apparatus EA may further include a sub-area in which an electronic module including various configurations is disposed on the second display surface RS, and is not limited to any one embodiment.

Referring to FIG. 1D, the electronic apparatus EA according to an embodiment may be folded based on a second folding axis FX2 extended in the first direction DR1. The electronic apparatus EA may be folded based on the second folding axis FX2 and transformed into an out-folding state so that the first display surface FS is exposed to the outside. In one or more embodiments, the electronic apparatus EA may be configured such that the in-folding or the out-folding operation is mutually repeated from the unfolding operation, but embodiments of this disclosure are not limited thereto.

In FIGS. 1A to 1D, folding based on one folding axis FX1 or FX2 is illustrated, but the number of folding axes and the number of non-folding areas according to the folding axis in the electronic apparatus according to an embodiment are not limited thereto. For example, the electronic apparatus may be folded based on multiple folding axes so that a portion of each of the first display surface FS and the second display surface RS faces each other. In addition, the first and second folding axes FX1 and FX2 are illustrated as being parallel to the long sides of the electronic apparatus EA, but embodiments of this disclosure are not limited thereto, and the first and second folding axes FX1 and FX2 may be parallel to the short sides of the electronic apparatus EA.

In the electronic apparatus EA, each of the first non-folding area NFA1 and the second non-folding area NFA2 may be defined as a portion having display surfaces FS and RS, parallel to a plane defined by the first direction axis DR1 and the second direction axis DR2 in a folded state, as illustrated in FIGS. 1A to 1D, and the folding area FA may be defined as an area between the first non-folding area NFA1 and the second non-folding area NFA2. The folding area FA may include a curved portion that is bent to have a predetermined curvature in a folded state.

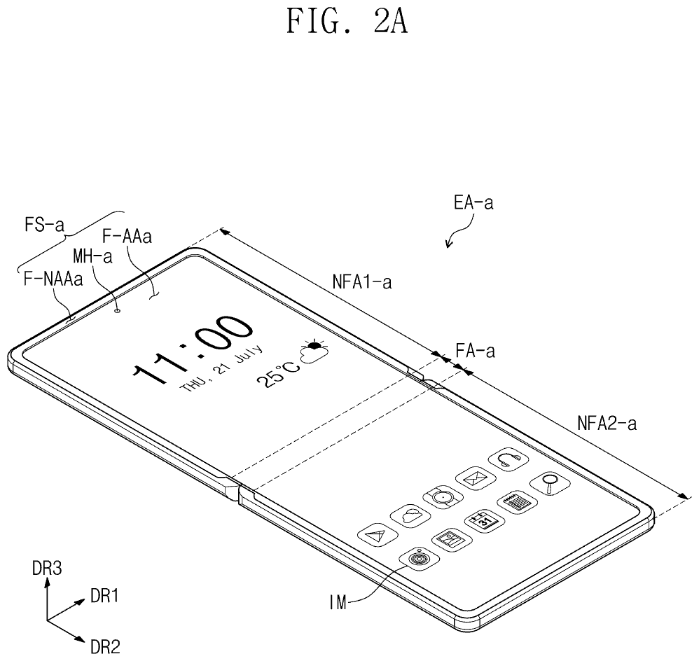

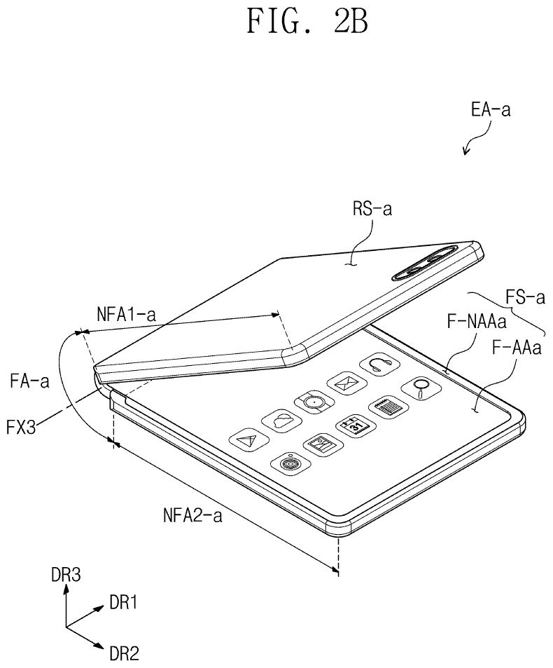

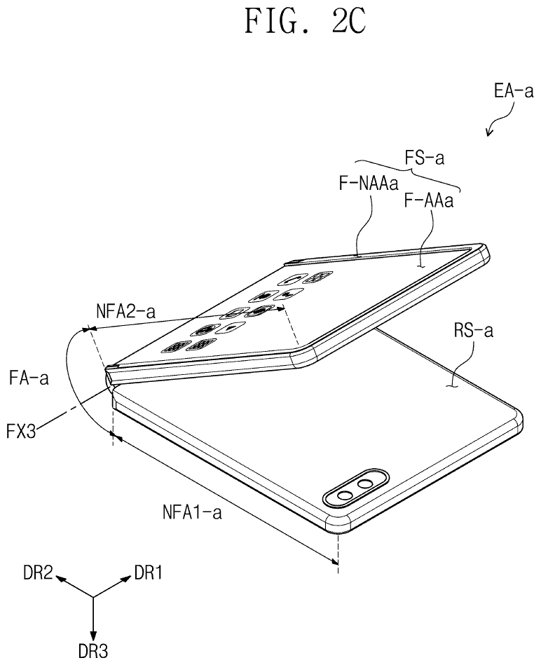

FIGS. 2A to 2C are perspective views illustrating an electronic apparatus EA-a according to another embodiment as disclosed herein. FIG. 2A is a perspective view illustrating an unfolded state of the electronic apparatus EA-a. FIGS. 2B and 2C are perspective views illustrating a folding operation of the electronic apparatus EA-a. FIG. 2B is a perspective view illustrating an in-folding operation of the electronic apparatus EA-a illustrated in FIG. 2A. FIG. 2C is a perspective view illustrating an out-folding operation of the electronic apparatus EA-a illustrated in FIG. 2A.

The electronic apparatus EA-a may be folded based on a third folding axis FX3 that is parallel to the first direction axis DR1. Referring to FIGS. 2B and 2C, the extending direction of the third folding axis FX3 may be parallel to the extending direction of the short sides of the electronic apparatus EA-a.

The electronic apparatus EA-a may be divided into a folding area FA-a, a first non-folding area NFA1-a adjacent to one side of the folding area FA-a, and a second non-folding area NFA2-a adjacent to the other side of the folding area FA-a. The first non-folding area NFA1-a and the second non-folding area NFA2-a may be spaced apart from each other with the folding area FA-a therebetween.

The folding area FA-a may be an area folded based on the third folding axis FX3. If the electronic apparatus EA-a is folded, the folding area FA-a may have a predetermined curvature and radius of curvature. The first non-folding area NFA1-a and the second non-folding area NFA2-a face each other, and the electronic apparatus EA-a may be in-folded so that the display surface FS-a is not exposed to the outside.

Referring to FIG. 2A, in one or more embodiments, the electronic apparatus EA-a may be visible to the user in an unfolded state (i.e., in a not folded state) through a display surface FS-a. As described with reference to FIGS. 1A to 1D, the display surface FS-a of the electronic apparatus EA-a may include an active area F-AAa, a peripheral area F-NAAa, and a sub-area MH-a. The active area F-AAa may be an area where an image IM is displayed and various forms of external inputs may be detected.

Referring to FIG. 2B, a back RS-a may be visible to the user in an in-folded state of the electronic apparatus EA-a of an embodiment. For example, the back RS-a may function as a second display surface that displays an image. In addition, the back RS-a may also be provided with a sub-area in which an electronic module including various configurations is disposed.

Referring to FIG. 2C, the electronic apparatus EA-a may be folded based on the third folding axis FX3 and transformed into an out-folding state in which one area of the back RS-a overlapping with the first non-folding area NFA1-a and the other area overlapping with the second non-folding area NFA2-a face each other.

FIG. 3 is an exploded perspective view of the electronic apparatus EA illustrated in FIG. 1A. Hereinafter, the description of the electronic apparatus EA may be equally applied to the electronic apparatus EA-a illustrated in FIGS. 2A to 2C.

FIG. 3 is an exploded perspective view illustrating the electronic apparatus EA of an embodiment. Referring to FIG. 3, the electronic apparatus EA may include an electronic module ELM and a display device DD. In addition, the electronic apparatus EA may further include a housing HAU. In one or more embodiments, the display device DD may include a display module DM and a protective member RM disposed on the display module DM. The display device DD may provide an image IM (FIG. 1A). The display device DD may have a module area DM-MH defined therein, and the electronic module ELM may be disposed to correspond to the module area DM-MH.

The protective member RM may be a configuration disposed on the uppermost of the electronic apparatus EA. An image IM (FIG. 1A) produced from the display module DM may be provided to a user by passing through the protective member RM. The protective member RM may be folded based on at least one of the folding axes FX1 and FX2 (FIGS. 1B and 1D). In an embodiment, the protective member RM may exhibit characteristics of preventing damage such as cracks during folding and facilitating repetition of folding and unfolding. Accordingly, the display device DD including the protective member RM according to an embodiment and the electronic apparatus EA including the same may exhibit excellent reliability.

The display device DD may further include an upper adhesive layer AP-R. The upper adhesive layer AP-R may be disposed between the display module DM and the protective member RM. The display module DM and the protective member RM may be combined through the upper adhesive layer AP-R. The upper adhesive layer AP-R may include a pressure sensitive adhesive (PSA), an optically clear adhesive film (OCA), or an optically clear adhesive resin layer (OCR). However, this is an illustrative embodiment and does not limit the disclosure. Unlike the drawing, the upper adhesive layer AP-R may be omitted.

The display module DM may display an image IM (FIG. 1A) according to an electrical signal and transmit/receive information about an external input. A display area DM-DA and a non-display area DM-NDA may be defined in the display module DM. In addition, a module area DM-MH may be defined in the display module DM.

The display area DM-DA may be defined as an area that emits an image IM (FIG. 1A) provided from the display module DM. The display area DM-DA of the display module DM may correspond to at least a portion of the first active area F-AA (FIG. 1A).

A driving circuit or driving wiring for driving the display area DM-DA may be disposed in the non-display area DM-NDA. The non-display area DM-NDA may be adjacent to the display area DM-DA. For example, the non-display area DM-NDA may surround the display area DM-DA. However, this is an illustration, and the non-display area DM-NDA may be defined in various shapes and is not limited to any one embodiment.

The module area DM-MH may correspond to the sub-area MH illustrated in FIG. 1A. An optical signal may move to the module area DM-MH. The module area DM-MH may be disposed within the display area DM-DA. However, this is an illustration, and is not limited to any one embodiment.

The electronic module ELM may be disposed to correspond to the module area DM-MH. The electronic module ELM may be an electronic component that outputs or receives an optical signal. For example, the electronic module ELM may include a camera module and/or a proximity sensor. The camera module may capture an external image through the module area DM-MH. However, illustrative embodiments do not limit embodiments of this disclosure. The electronic module ELM may further include a built-in module and/or an external module. The built-in module may include a sensor module, an antenna module, and an audio output module. The external module may include a light module, and a communication module.

The display module DM may include a folding display part FP-D and non-folding display parts NFP1-D and NFP2-D. The folding display part FP-D may correspond to a part corresponding to the folding area FA (FIG. 1A), and the non-folding display parts NFP1-D and NFP2-D may correspond to a part corresponding to the non-folding areas NFA1 and NFA2 (FIG. 1A).

A housing HAU may include a material having relatively high rigidity. For example, the housing HAU may include a plurality of frames and/or plates composed of glass, plastic, or metal. The housing HAU may provide a predetermined receiving space. The display module DM may be accommodated within the receiving space and protected from external impact.

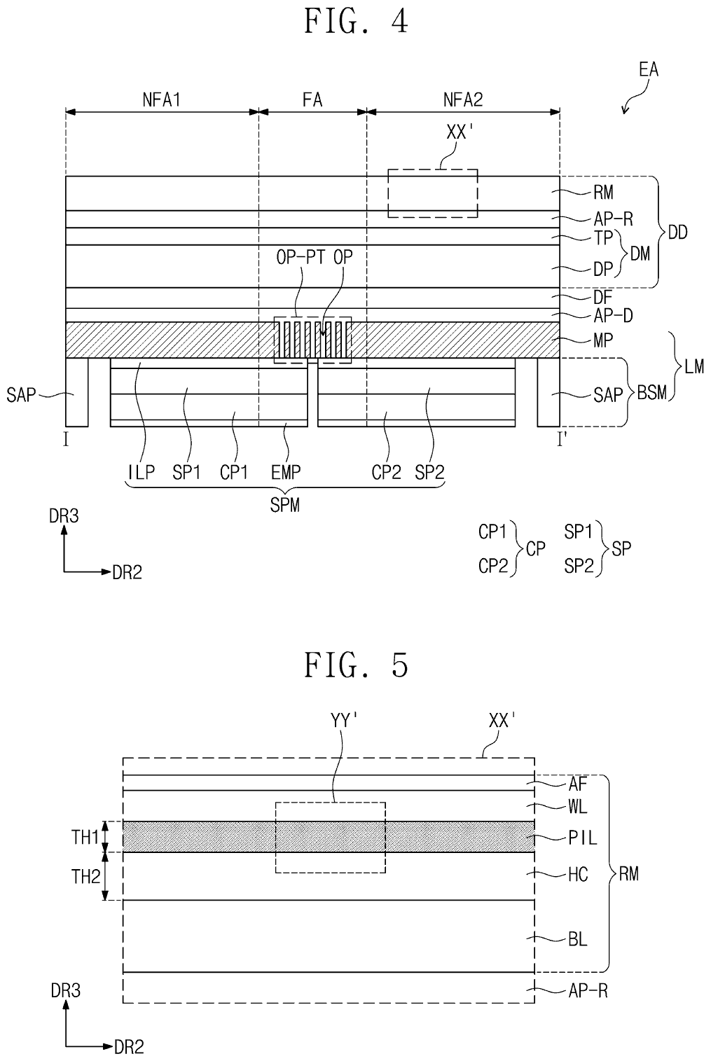

FIG. 4 is a cross-sectional view showing a portion corresponding to line I-I′ shown in FIG. 3. FIG. 4 may be a cross-sectional view showing an electronic apparatus EA of an embodiment. In FIG. 4, the housing HAU (FIG. 3) is omitted for convenience of explanation.

Referring to FIG. 4, the electronic apparatus EA may further include a lower module LM, a lower adhesive layer AP-D, and a lower protective film DF. The lower module LM, the lower adhesive layer AP-D, and the lower protective film DF may be disposed between the display device DD and the housing HAU (FIG. 3).

The lower module LM may be disposed under the display module DM. The lower module LM may include a support plate MP and a lower support member BSM. The lower module LM illustrated in FIG. 4 is an exemplary configuration, and the combination of the configurations included in the lower module LM in the electronic apparatus EA of an embodiment may be changed depending on the size of the electronic apparatus EA, the shape of the electronic apparatus EA, or the operating characteristics of the electronic apparatus EA.

The support plate MP may include a metal material or a polymer material. For example, the support plate MP may be formed by including stainless steel, aluminum, or an alloy thereof. Alternatively, the support plate MP may be formed of a polymer material. A plurality of openings OP may be defined in the support plate MP. The support plate MP may include an opening pattern OP-PT in which a plurality of openings OP are defined. The opening pattern OP-PT may be formed in the folding area FA.

The lower support member BSM may include a support member SPM and a charging part SAP. On the plane, the support member SPM may be configured to overlap most of the area of the display module DM. The charging part SAP may be configured to be disposed on the outside of the support member SPM and overlap the outside of the display module DM.

The support member SPM may include at least one of a support layer SP, a cushion layer CP, a shielding layer EMP, and an interlayer bonding layer ILP. The configuration of the support member SPM illustrated in FIG. 4 is an illustrative embodiment, and embodiments of this disclosure are not limited thereto. For example, some of the support layer SP, the cushion layer CP, the shielding layer EMP, and the interlayer bonding layer ILP may be omitted, or the stacking order may be changed to a different order from that illustrated in FIG. 4, or an additional configuration other than the illustrated configurations may be further included in the support member SPM.

The support layer SP may include a metal material or a polymer material. The support layer SP may be disposed under the support plate MP. For example, the support layer SP may be a metal substrate of a thin film. The support layer SP may include a first sub-support layer SP1 and a second sub-support layer SP2 spaced apart in the second direction DR2. The first sub-support layer SP1 and the second sub-support layer SP2 may be spaced apart in an area corresponding to the folding axes FX1 and FX2 (FIGS. 1A and 1D). The support layer SP may be provided as the first sub-support layer SP1 and the second sub-support layer SP2 spaced apart in the folding area FA, thereby improving the folding characteristics of the electronic apparatus EA.

The cushion layer CP may be disposed under the support layer SP. The cushion layer CP may prevent the pressing phenomenon and plastic deformation of the support plate MP due to external impact and force. The cushion layer CP may improve the impact resistance of the electronic apparatus EA. The cushion layer CP may include an elastomer such as a sponge, foam, or urethane resin. In addition, the cushion layer CP may be formed by including at least one of an acrylic polymer, a urethane-based polymer, a silicone-based polymer, and an imide-based polymer. However, this is an illustrative embodiment, and embodiments of this disclosure are not limited thereto.

The cushion layer CP may include a first sub-cushion layer CP1 and a second sub-cushion layer CP2 spaced apart in the second direction DR2. The first sub-cushion layer CP1 and the second sub-cushion layer CP2 may be spaced apart from each other at a portion corresponding to the folding axes FX1 and FX2 (FIGS. 1B and 1D). The cushion layer CP may improve the folding characteristics of the electronic apparatus EA by providing the first sub-cushion layer CP1 and the second sub-cushion layer CP2 spaced apart in the folding area FA.

The shielding layer EMP may be an electromagnetic shielding layer or a heat dissipation layer. In addition, the shielding layer EMP may function as a bonding layer.

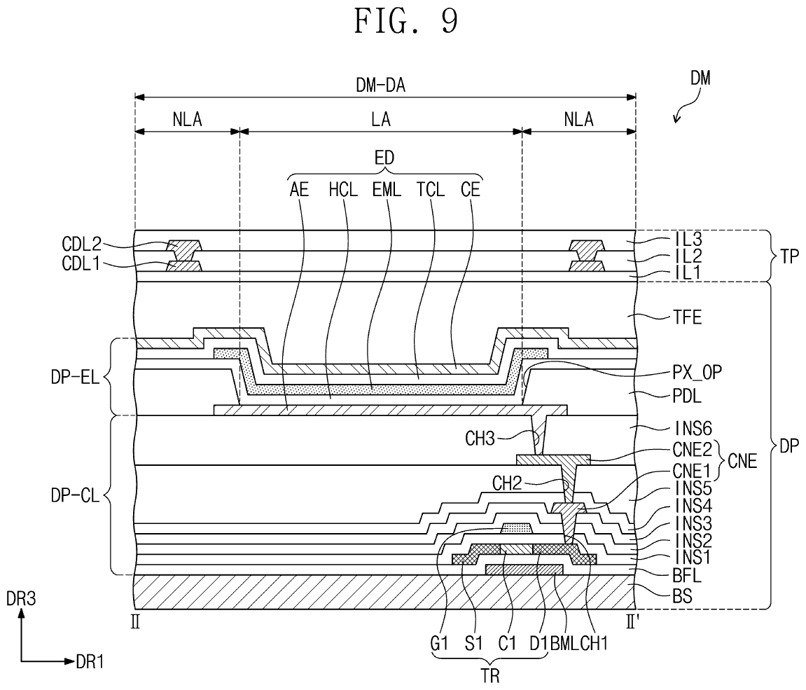

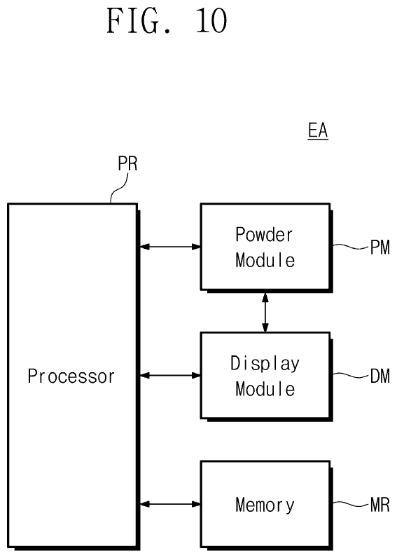

The interlayer bonding layer ILP may bond the components of the support plate MP and the support member SPM. The interlayer bonding layer ILP may be provided in the form of a bonding resin layer or an adhesive tape. In FIG. 9, the interlayer bonding layer ILP is illustrated as being provided as two components spaced apart in an area corresponding to the folding axes FX1 and FX2 (FIGS. 1B and 1D), but embodiments of this disclosure are not limited thereto. Various embodiments may differ from the drawings or illustrative embodiments. For example, the interlayer bonding layer ILP may be provided as one layer that is not spaced apart in an area corresponding to the folding axes FX1 and FX2 (as shown in FIGS. 1B and 1D).

The charging part SAP may be disposed on the outside of the support layer SP and the cushion layer CP. The charging part SAP may be disposed between the support plate MP and the housing HAU (FIG. 3). The charging part SAP may fill the space between the support plate MP and the housing HAU (FIG. 3) and may fix the support plate MP.

The lower protective film DF may be disposed between the display module DM and the support plate MP. The lower protective film DF may be disposed under the display module DM to protect the back of the display module DM. The lower protective film DF may entirely overlap the display module DM. The lower protective film DF may include a polymer material. For example, the lower protective film DF may be a polyimide film or a polyethylene terephthalate film. However, this is an illustration, and the lower protective film DF is not limited thereto.

A lower adhesive layer AP-D may be disposed between the support plate MP and the lower protective film DF. The support plate MP and the lower protective film DF may be combined through the lower adhesive layer AP-D. The lower adhesive layer AP-D may include a pressure sensitive adhesive (PSA), an optically clear adhesive film (OCA), or an optically clear adhesive resin layer (OCR). However, this is an illustrative embodiment, and embodiments of this disclosure are not limited thereto. Various embodiments may differ from the drawings or illustrative embodiments. For example, the lower adhesive layer AP-D may be omitted.

The display module DM may include a display panel DP and an input sensing part TP disposed on the display panel DP. The display panel DP may be configured to substantially produce an image. The display panel DP according to an embodiment may be folded based on the folding axes FX1 and FX2 (FIGS. 1B and 1D).

The input sensing part TP may detect an external input, change the external input into a predetermined input signal, and provide the input signal to the display panel DP. For example, the input sensing part TP may be a touch detection part that detects a touch. The input sensing part TP may recognize a direct touch of a user, an indirect touch of a user, a direct touch of an object, or an indirect touch of an object.

The input sensing part TP may detect at least one among a position of a touch applied from the outside and a strength (pressure) of the touch. In one or more embodiments, the input sensing part TP may have various structures or be composed of various materials, and is not limited to any one embodiment. For example, the input sensing part TP may detect an external input in a capacitive manner. The display panel DP may receive an input signal from the input sensing part TP and generate an image corresponding to the input signal.

FIG. 5 is an enlarged cross-sectional view showing an area XX′ in FIG. 4. FIG. 5 may be a cross-sectional view specifically showing the configuration of the protective member RM.

Referring to FIG. 5, the protective member RM may include a base layer BL, a hard coating layer HC, a primer layer PIL, and a first low refractive index layer WL. The protective member RM may further include an anti-fingerprint layer AF disposed on the first low refractive index layer WL. The anti-fingerprint layer AF may include an anti-fingerprint agent and may further include an anti-static agent, or the like.

The hard coating layer HC may be disposed on the base layer BL. The primer layer PIL may be disposed between the hard coating layer HC and the first low refractive index layer WL. The primer layer PIL may be disposed directly between the hard coating layer HC and the first low refractive index layer WL.

In the description, if an element is directly disposed/formed on another element, it means that no third element is disposed/formed between an element and another element. That is, if an element is disposed/formed directly on another element, it means that the element is in contact with the other element.

The base layer BL may be a member providing a base surface on which the hard coating layer HC, the primer layer PIL and the first low refractive index layer WL are disposed. For example, the base layer BL may be a polymer film having flexibility. The base layer BL may include at least one of polyethylene terephthalate, polyimide, polyacrylate, polymethyl acrylate, polymethyl methacrylate, polycarbonate, polyethylene naphthalate, polyvinylidene chloride, polyvinylidene difluoride, polystyrene, or an ethylene-vinyl alcohol copolymer. For example, the base layer BL may include polyethylene terephthalate.

The hard coating layer HC may exhibit high elongation and high hardness. The hard coating layer HC may include a hard coating agent including at least one of an organic composition, an inorganic composition, and an organic-inorganic composite composition. For example, the hard coating agent forming the hard coating layer HC may include a silsesquioxane resin. In addition, the hard coating agent forming the hard coating layer HC may further include an acrylate-based (i.e., an acrylate-containing) resin and/or a siloxane resin.

The silsesquioxane resin may include at least one of a random structure, a partial cage structure, a ladder structure, or a cage structure. Each of the structures exhibits a different peak in the IR spectrum. The silsesquioxane resin may include at least one of first to fifth moiety units. The first to fifth moiety units may be represented by Formulas S-1 to S-5 below, respectively.

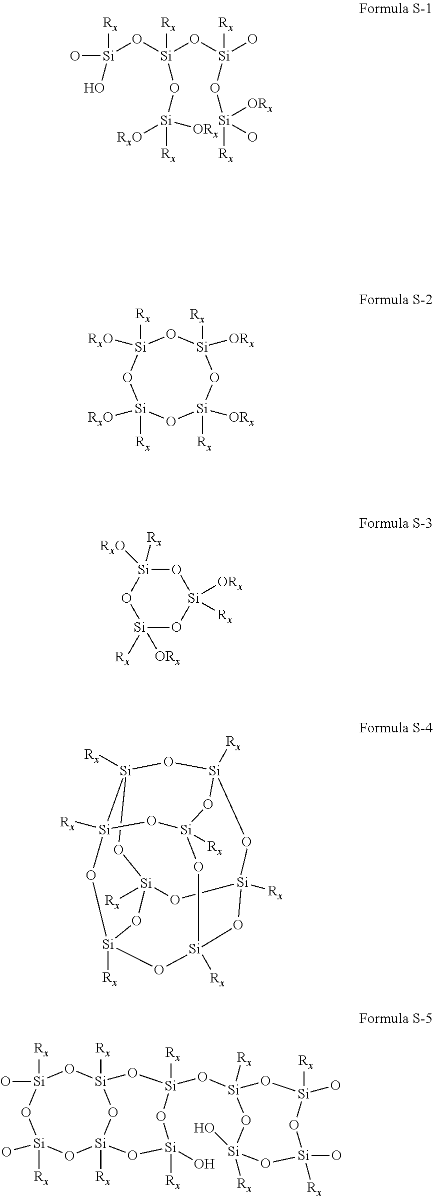

The first moiety unit represented by Formula S-1 includes a random structure. The second moiety unit represented by Formula S-2 and the third moiety unit represented by Formula S-3 each includes a partial cage structure. The fourth moiety unit represented by Formula S-4 includes a cage structure. The fifth moiety unit represented by Formula S-5 includes a ladder structure. In Formulas S-1 to S-5, a plurality of Rx may be each independently a hydrogen atom, an alkyl group of 1 to 60 carbon atoms, an alkenyl group of 2 to 60 carbon atoms, an alkoxy group of 1 to 60 carbon atoms, or an aryl group of 6 to 60 ring-forming carbon atoms.

In addition, the hard coating agent may further include inorganic particles. In the hard coating agent, the inorganic particles may be provided to improve the hardness of the hard coating layer HC. The inorganic particles may be surface-treated with an organic material such as silane to increase the dispersion in the hard coating agent. For example, the inorganic particles may include at least one of SiO₂, TiO₂, Al₂O₃, ZrO₂, ZnO, AlN, or Si₃N₄.

For example, the refractive index of the hard coating layer HC may be about 1.51. However, this is an illustration, and the refractive index of the hard coating layer HC is not limited thereto.

The first low refractive index layer WL may be a layer having a relatively low refractive index. For example, the refractive index of the first low refractive index layer WL may be about 1.3 to about 1.5. The refractive index of the first low refractive layer WL may be about 1.46, or 1.46, or about 1.48, or 1.48, at a wavelength of about 550 nm.

The first low refractive index layer WL may include an inorganic oxide. The first low refractive index layer WL may include a Si-containing inorganic oxide. The first low refractive index layer WL may include at least one of silicon dioxide (SiO₂) or a first substitutional solid liquid. The silicon dioxide may have polymorphs. The first substitutional solid liquid may include silicon atoms, aluminum atoms and oxygen atoms. The first substitutional solid liquid may be Si₉Al₂O₁₀. However, this is an illustration, and the first low refractive index layer WL may further include a material having low refractive index properties known in the art.

The refractive index of the primer layer PIL may be higher than the refractive index of the first low refractive index layer WL. The refractive index of the primer layer PIL may be about 1.62 to about 1.91. For example, the refractive index of the primer layer PIL may be about 1.62 to about 1.86. Otherwise, the refractive index of the primer layer PIL may be about 1.67 to about 1.91. For example, the refractive index of the primer layer PIL may be about 1.81, or 1.81, or about 1.72, or 1.72, at a wavelength of about 550 nm.

The thickness TH1 of the primer layer PIL may be smaller than the thickness TH2 of the hard coating layer HC. The thickness TH1 of the primer layer PIL may be about 70 nm to about 90 nm. For example, the thickness TH1 of the primer layer PIL may be about 83 nm or about 75 nm, and the thickness TH2 of the hard coating layer HC may be about 3 μm, or 3 μm.

The protective member RM including the primer layer PIL and the first low refractive index layer WL disposed on the primer layer PIL may exhibit excellent anti-reflection characteristics. The structure including the primer layer PIL and the first low refractive index layer WL disposed on the primer layer PIL may have an specular component included (SCI) reflectivity of about 1.0% or less. The first low refractive index layer WL having a relatively low refractive index may be disposed on a primer layer PIL having a relatively high refractive index, so that a protective member RM according to an embodiment may exhibit excellent anti-reflection characteristics. In addition, the protective member RM according to an embodiment may exhibit reduced compressive stress in an area corresponding to the folding area FA (FIG. 1A) and excellent folding reliability by including a relatively small number of components. In addition, the protective member RM according to an embodiment may exhibit excellent folding reliability even at high and low temperatures.

In a common, known protective member, an anti-reflection layer includes a plurality of high refractive index layers and a plurality of low refractive index layers alternately disposed in multiple layers, and includes five or more layers. In this way, the anti-reflection layer in which five or more layers are stacked generates cracks when folding and unfolding are repeated. In a portion of the anti-reflection layer corresponding to a folding area, cracks occur due to compressive stress, and cracks also occur in a hard coating layer adjacent to the anti-reflection layer. In contrast, the protective member RM according to an embodiment as described herein includes the primer layer PIL having a relatively high refractive index, so that the thickness of the configuration having anti-reflection properties (i.e., the primer layer PIL and the first low refractive index layer WL) may be reduced, and excellent anti-reflection properties and excellent folding reliability may be exhibited.

In an embodiment, the primer layer PIL may include a metal compound and a polar compound. The metal compound may include at least one of a titanium alkoxide oligomer, a zirconium alkoxide oligomer, or a zirconium chelate compound. In the description, the polar compound means a compound including a functional group having polarity.

A primer layer PIL including a titanium alkoxide oligomer may exhibit a relatively high refractive index. The refractive index of the primer layer PIL including the titanium alkoxide oligomer and the polar compound may be about 1.67 to about 1.91.

The titanium alkoxide oligomer may include a titanium atom and an alkoxy group bonded to the titanium atom. In addition, the titanium alkoxide oligomer may include a hydroxy group bonded to the titanium atom. The number of carbon atoms included in the titanium alkoxide oligomer may be 96 to 320. For example, the number of carbon atoms of the alkoxy group in the titanium alkoxide oligomer may be 96 to 320. The alkoxy group is an alkyl group bonded to an oxygen atom, and the alkyl group may be linear or branched. A plurality of the alkoxy groups in the titanium alkoxide oligomer may be present. In an embodiment, at least one of the plurality of alkoxy groups may include a butyl group, a 2-ethylhexyl group, or a hexyl group. The titanium alkoxide oligomer is prepared using titanium alkoxide as a raw material and may include multiple moieties (i.e., Ti—O—Ti) in which titanium atoms are bonded to oxygen atoms. The titanium alkoxide oligomer may include a polytitanoxane compound. The titanium alkoxide oligomer having 96 to 320 carbon atoms exhibits excellent adhesion to the hard coating layer HC and may prevent (or minimize) crack occurrence during repeated folding and unfolding. In addition, the primer layer PIL including the titanium alkoxide oligomer having 96 to 320 carbon atoms may be optically transparent and exhibit excellent thickness stability.

In contrast, a primer layer including a titanium alkoxide oligomer having less than 96 carbon atoms does not prevent crack occurrence. A primer layer including a titanium alkoxide oligomer having more than 320 carbon atoms exhibits reduced adhesion.

The primer layer PIL may be formed by co-depositing the titanium alkoxide oligomer and the polar compound. The titanium alkoxide oligomer and the polar compound may be combined to form the primer layer PIL. The titanium alkoxide oligomer may be partially thermally decomposed, thereby dissociating bonds between titanium atoms and oxygen atoms and forming bonds between titanium atoms and/or oxygen atoms and the polar compound. The refractive index of the primer layer PIL may be controlled depending on the baking (heating) temperature of the titanium alkoxide oligomer after deposition. The refractive index of the primer layer PIL may be controlled depending on the pyrolysis temperature at which the titanium alkoxide oligomer is partially thermally decomposed. For example, the refractive index of the primer layer PIL formed from the titanium alkoxide oligomer that is easily thermally decomposed at about 100° C. may be about 1.71, or 1.71. The refractive index of the primer layer PIL formed from the titanium alkoxide oligomer that is easily thermally decomposed at about 115° C. may be about 1.81, or 1.81. The refractive index of the primer layer PIL formed from the titanium alkoxide oligomer which is easily thermally decomposed at about 120° C. may be about 1.82, or 1.82. The refractive index of the primer layer PIL formed from the titanium alkoxide oligomer which is easily thermally decomposed at about 140° C. may be about 1.85, or 1.85.

The titanium alkoxide oligomer may include at least one of a first moiety represented by Formula 1 below and a second moiety represented by Formula 2 below. The first moiety may be tetra-N-butyl orthotitanate tetramer. The second moiety may be tetrakis(2-ethylhexyl) orthotitanate.

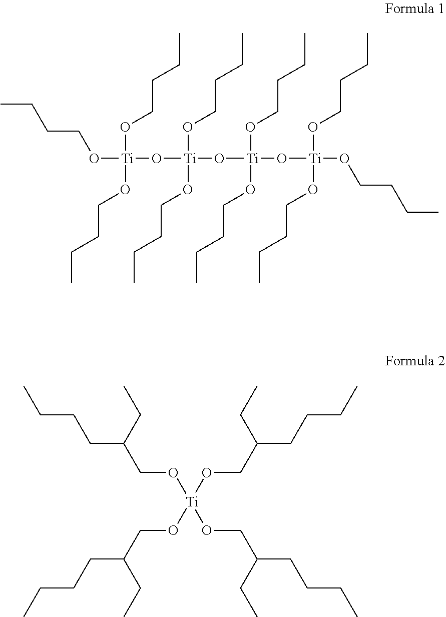

For example, the titanium alkoxide oligomer may include 3 to 8, 3 to 5, or 4 to 6 first moieties. The titanium alkoxide oligomer may include 3 to 8, 5 to 8, or 4 to 6 second moieties.

The molecular formula of the first moiety represented by Formula 1 may be C₄₀H₉₀O₁₃Ti₄. If the titanium alkoxide oligomer includes 8 first moieties, the number of carbon atoms in the titanium alkoxide oligomer may be 320. The molecular formula of the second moiety represented by Formula 2 may be C₃₂H₆₈O₄Ti. If the titanium alkoxide oligomer includes 3 second moieties, the number of carbon atoms in the titanium alkoxide oligomer may be 96.

The titanium alkoxide oligomer may enhance the adhesion of the primer layer PIL to the hard coating layer HC. The titanium alkoxide oligomer may enhance the adhesion of the primer layer PIL to the hard coating layer HC by covalent bonding and/or coordination bonding with a material constituting the hard coating layer HC (e.g., a hydroxyl group of a silsesquioxane resin). The primer layer PIL including the titanium alkoxide oligomer may be optically transparent and exhibit excellent adhesion.

The primer layer PIL including a zirconium material exhibits hydrophilicity and may exhibit excellent wear resistance. The primer layer PIL including a zirconium material may exhibit high adhesion to the hard coating layer HC and the first low refractive index layer WL. The primer layer PIL including a zirconium material may relieve bending stress due to a difference in thermal expansion coefficients of a substrate (for example, the hard coating layer HC and the first low refractive index layer WL) constituting the protective member RM.

The primer layer PIL including a zirconium material may exhibit a relatively high refractive index. Two layers constituting the primer layer PIL including a zirconium material and the first low refractive index layer WL may function as an anti-reflection layer. The refractive index of the primer layer PIL including a zirconium material and a polar compound may be about 1.62 to about 1.86. In the description, the zirconium material means a zirconium alkoxide oligomer and/or a zirconium chelate compound.

The zirconium alkoxide oligomer may include a zirconium atom and an alkoxy group bonded to a zirconium atom. In addition, the zirconium alkoxide oligomer may include a hydroxyl group bonded to a zirconium atom.

The primer layer PIL may be formed by co-depositing a zirconium alkoxide oligomer and a polar compound. The zirconium alkoxide oligomer and the polar compound may be bonded to form the primer layer PIL. The zirconium alkoxide oligomer may be partially thermally decomposed, thereby dissociating the bond between the zirconium atom and the oxygen atom, and forming a bond between the zirconium atom and/or the oxygen atom and the polar compound. The refractive index of the primer layer PIL may be controlled depending on the baking temperature of the zirconium alkoxide oligomer. The refractive index of the primer layer PIL may be controlled depending on the thermal decomposition temperature at which the zirconium alkoxide oligomer is partially thermally decomposed. For example, the refractive index of the primer layer PIL formed from the zirconium alkoxide oligomer that is easily thermally decomposed at about 105° C. may be about 1.72.

For example, the primer layer PIL may include a zirconium alkoxide oligomer, a zirconium chelate compound, and a polar compound. The zirconium chelate compound may exhibit an effect of facilitating the formation of a thin film containing zirconium oxide (that is, the primer layer PIL). If the primer layer PIL includes a zirconium alkoxide oligomer, a zirconium chelate compound, and a polar compound, the ratio of a first weight to a second weight may be about 7:3 based on the sum of the first weight of the zirconium alkoxide oligomer and the second weight of the zirconium chelate compound. If the ratio of the first weight and the second weight is about 7:3, characteristics in which folding and unfolding repetition are easy without increasing the thickness of the protective member RM may be shown. However, this is an illustration, and the ratio of the first weight and the second weight is not limited thereto.

The zirconium chelate compound may include zirconium acetylacetonate. The zirconium alkoxide oligomer may include at least one of a third moiety represented by Formula 3 and a fourth moiety represented by Formula 4 below.

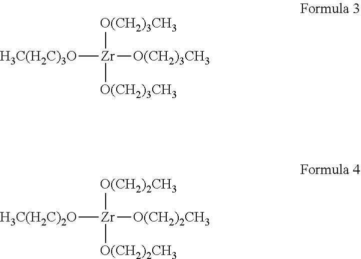

The fourth moiety represented by Formula 4 may be zirconium(IV) tetrapropoxide. The primer layer PIL including zirconium(IV) tetrapropoxide may show high hardness characteristics. The molecular formula of Formula 3 may be C₁₆H₃₆O₄Zr. For example, the zirconium alkoxide oligomer may include three to five third moieties.

The polar compound may have high affinity for an inorganic oxide. The polar compound may be an adhesion-imparting agent having a polar group having high affinity for an inorganic oxide. The primer layer PIL including the polar compound may have improved adhesion to the first low refractive index layer WL including the inorganic oxide. The polar compound may include an amine group. The polar compound may include at least one of 2-(2-aminoethoxy)ethylamine, 4-(2-aminoethoxy)phenol, or triethanolamine. Formulae P-1 to P-3 represent 2-(2-aminoethoxy)ethylamine, 4-(2-aminoethoxy)phenol, and triethanolamine, respectively.

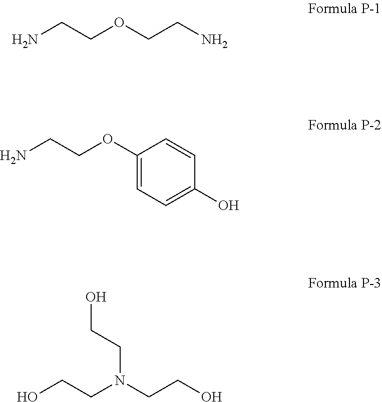 [SMILES: NCCOCCN ; NCCOc1ccc(O)cc1 ; OCCN(CCO)CCO]

2-(2-Aminoethoxy)ethylamine, 4-(2-aminoethoxy)phenol, and triethanolamine may have high affinity for Si-containing inorganic oxides (for example, SiO₂). A primer layer PIL including the polar compound may prevent cracking of the protective member RM, thereby contributing to improving folding reliability.

For example, the primer layer PIL may include the first moiety as a titanium alkoxide oligomer, and may include at least one of 2-(2-aminoethoxy)ethylamine and 4-(2-aminoethoxy)phenol as a polar compound. The primer layer PIL may include the second moiety described above as a titanium alkoxide oligomer and may include triethanolamine as a polar compound. The primer layer PIL includes at least one of the third and fourth moieties described as the zirconium alkoxide oligomer, and at least one of 2-(2-aminoethoxy)ethylamine or 4-(2-aminoethoxy)phenol as the polar compound. The primer layer PIL may include the third moiety and zirconium acetylacetonate as the zirconium compound, and may include triethanolamine as the polar compound.

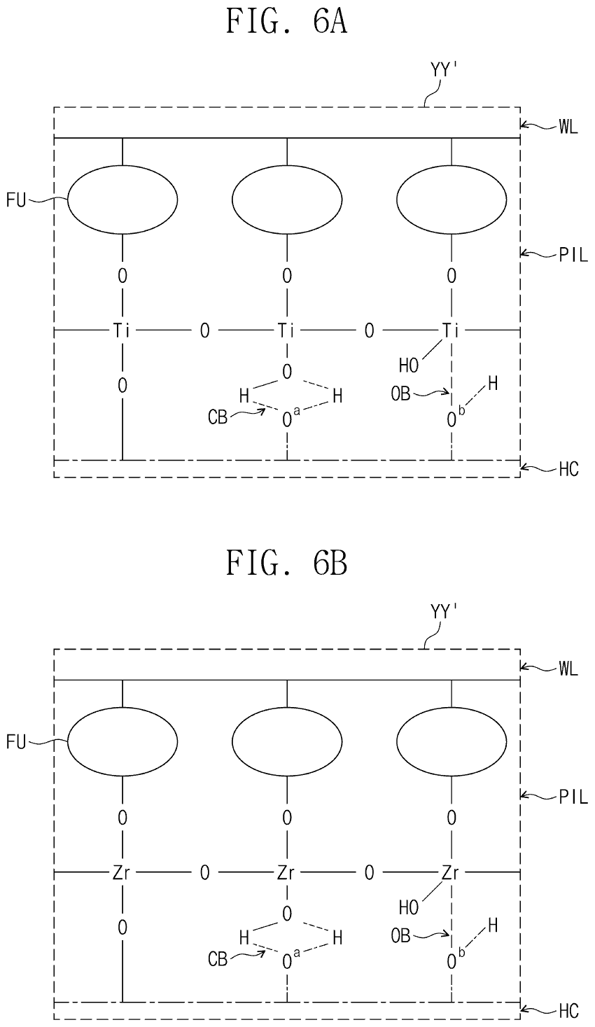

FIG. 6A is an enlarged cross-sectional view showing an area YY′ in FIG. 5. FIG. 6A may be a cross-sectional view specifically showing the primer layer PIL. In FIG. 6A, O^{a} and O^{b} are oxygen atoms denoted a and b for convenience of explanation. In FIG. 6A, a first hydroxyl group including O^{a} and a second hydroxyl group including O^{b} may be included in the hard coating layer HC. For example, a silsesquioxane resin included in the hard coating layer HC may include the first and second hydroxyl groups.

Referring to FIG. 6A, the primer layer PIL may include a titanium alkoxide oligomer and a polar compound FU. The polar compound FU may be bonded to the oxygen atom of the titanium alkoxide oligomer. The polar compound FU may be adhered to the first low refractive index layer WL, and the titanium alkoxide oligomer may be adhered to the hard coating layer HC. The polar compound FU has high affinity for inorganic oxides, and may exhibit excellent adhesion to the first low refractive index layer WL including the inorganic oxide.

In the titanium alkoxide oligomer, a hydroxyl group may be bonded to at least one of a plurality of titanium atoms. The hydroxyl group of the titanium alkoxide oligomer may form a covalent bond with the first hydroxyl group. The titanium atom of the titanium alkoxide oligomer may form a coordinate bond with the second hydroxyl group. In FIG. 6A, “CB” represents a covalent bond, and “OB” represents a coordinate bond. The titanium alkoxide oligomer may form a covalent bond and a coordinate bond with the hydroxyl group of the hard coating layer HC, and may exhibit excellent adhesion. Although not shown, the titanium atoms at the left and right edges in FIG. 6 may further bond to adjacent oxygen atoms.

FIG. 6B is a cross-sectional view showing an area YY′ according to another embodiment. Hereinafter, in the description of FIG. 6B, the content that overlaps with the contents described referring to FIGS. 1A to 6A will not be described again, and differences will be mainly explained.

The primer layer PIL may include a zirconium alkoxide oligomer and a polar compound FU. The polar compound FU may be combined with the oxygen atom of the zirconium alkoxide oligomer. The polar compound FU may be in close contact with the first low refractive index layer WL, and the zirconium alkoxide oligomer may be in close contact with the hard coating layer HC.

In the zirconium alkoxide oligomer, a hydroxyl group may be combined with at least one of a plurality of zirconium atoms. The hydroxyl group of the zirconium alkoxide oligomer may form a covalent bond with the first hydroxyl group. The zirconium atom of the zirconium alkoxide oligomer may form a coordination bond with a second hydroxyl group. The zirconium alkoxide oligomer may form a covalent bond and a coordination bond with the hydroxyl groups of the hard coating layer HC, thereby exhibiting excellent adhesion. Although not shown, zirconium atoms may be further combined with adjacent oxygen atoms in the left and right edges of FIG. 6B.

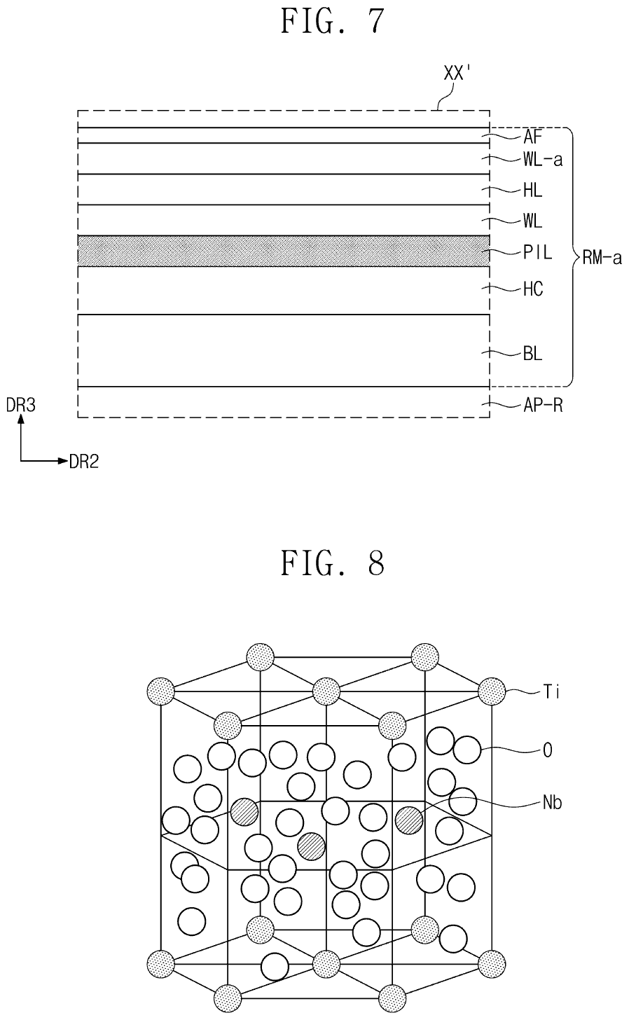

FIG. 7 is a cross-sectional view showing an area XX′ according to one or more embodiments. Hereinafter, in the description of FIG. 7, the overlapping contents described with reference to FIGS. 1A to 6 will not be described again, and differences will be mainly described.

Compared to the protective member RM illustrated in FIG. 5, the protective member RM-a illustrated in FIG. 7 is different in that a high refractive index layer HL and a second low refractive index layer WL-a are further included. Referring to FIG. 7, the protective member RM-a may further include a high refractive index layer HL disposed on the first low refractive index layer WL and a second low refractive index layer WL-a disposed on the high refractive index layer HL.

The refractive index of the second low refractive index layer WL-a may be about 1.3 to about 1.5. The refractive index of the second low refractive index layer WL-a may be about 1.46 at a wavelength of about 550 nm. The second low refractive index layer WL-a may include an inorganic oxide. The second low refractive index layer WL-a may include a Si-containing inorganic oxide. The second low refractive index layer WL-a may include silicon dioxide (SiO₂). The silicon dioxide may have a polymorph. However, this is an illustration, and the second low refractive index layer WL-a may further include a material having low refractive index properties known in the art.

The refractive index of the high refractive index layer HL may be about 1.6 to about 2.5. For example, the refractive index of the high refractive index layer HL may be about 2.17, or 2.17, at a wavelength of about 550 nm.

The high refractive index layer HL may be formed by providing niobium pentoxide (Nb₂O₅) and titanium dioxide (TiO₂). The high refractive index layer HL may include a second substitutional solid solution including niobium atoms, titanium atoms, and oxygen atoms. The niobium atoms, titanium atoms, and oxygen atoms of niobium pentoxide (Nb₂O₅) and titanium dioxide (TiO₂) may constitute a second substitutional solid solution. For example, the high refractive index layer HL may include a second substitutional solid solution of Ti₁₄Nb₃O₃₅. The high refractive index layer HL including the second substitutional solid solution of Ti₁₄Nb₃O₃₅ may have a refractive index of about 2.17 at a wavelength of about 550 nm.

FIG. 8 is a diagram showing a second substitutional solid solution of Ti₁₄Nb₃O₃₅. The second substitutional solid solution of Ti₁₄Nb₃O₃₅ may include a close-packed hexagonal lattice structure. The second substitutional solid solution of Ti₁₄Nb₃O₃₅ has high chemical bonding strength and may increase the density of a film. A high refractive index layer HL including the second substitutional solid solution may exhibit high density characteristics of a film.

Table 1 below shows the SCI reflectivity of the protective member of the Comparative Example and Examples. The reflectivity of the Comparative Example was measured by a spectrophotometer CM-3700A (Konica Minolta, Inc.), and the reflectivity of Examples 1 to 3 are simulation results. In Table 1, the SCI reflectivity is a value at a wavelength of about 550 nm. According to a relative visibility curve, green light corresponds to light that has high influence on reflectivity that deteriorates the display quality of a display device, and the wavelength of about 550 nm corresponds to green light. The ratio of the visibility to light of a given wavelength (about 380 nm to about 760 nm) with the maximum visibility being 1 is referred to the specific visibility, and a specific visibility curve is a curve that represents the specific visibility.

The protective member of the Comparative Example does not include a primer layer, and includes three low refractive index layers and two high refractive index layers on a hard coating layer. In the protective member of the Comparative Example, the three low refractive index layers and the two high refractive index layers are alternately disposed, and the low refractive index layer, the high refractive index layer, the low refractive index layer, the high refractive index layer, and the low refractive index layer are sequentially stacked.

The protective members of Examples 1 to 3 include a primer layer, and are protective members according to an embodiment. In the protective members of Examples 1 and 2, the base layer is a polyethylene terephthalate film having a thickness of about 65 μm, the hard coating layer has a thickness of about 3 μm, and the primer layer has a thickness of about 83 nm. In the protective members of Examples 1 and 2, the refractive index of the primer layer is about 1.81, and a titanium alkoxide oligomer is included.

The protective member of Example 1 includes a primer layer disposed on a hard coating layer and a first low refractive index layer disposed on the primer layer. The thickness of the first low refractive index layer in the protective member of Example 1 is about 92 nm. The protective member of Example 1 may include a configuration as illustrated in FIG. 5.

The protective member of Example 2 includes a primer layer, a first low refractive index layer, a high refractive index layer, and a second low refractive index layer sequentially stacked on a hard coating layer. The thickness of the first low refractive index layer in the protective member of Example 2 is about 10 nm, the thickness of the high refractive index layer is about 83 nm, and the thickness of the second low refractive index layer is about 100 nm. The protective member of Example 2 may include a configuration as illustrated in FIG. 7.

In the protective member of Example 3, the base layer is a polyethylene terephthalate film with a thickness of about 65 μm, the thickness of the hard coating layer is about 3 μm and the thickness of the primer layer is about 75 nm. In the protective member of Example 3, the refractive index of the primer layer is about 1.72 and a zirconium alkoxide oligomer is included. The protective member of Example 3 includes a primer layer disposed on the hard coating layer and a first low refractive index layer disposed on the primer layer. In the protective member of Examples 3, the thickness of the first low refractive index layer is about 95 nm. The protective member of Example 3 may include the same configuration as shown in FIG. 5. The protection member of Example 3 has an average reflectivity of about 0.50%, showing excellent average reflectivity. The average reflectivity means the reflectivity of light in a visible light wavelength area (that is, the wavelength of about 380 nm to about 760 nm).

TABLE 1

| | Reflectivity (at 550 nm) |
|---|---|
| Comparative Example | 0.49% |
| Example 1 | 0.14% |
| Example 2 | 0.05% |
| Example 3 | 0.17% |

Referring to Table 1, it can be seen that the protective members of Examples 1 to 3 exhibit low reflectivity compared to the protective member of the Comparative Example. It can be seen that the protective members of Examples 1 to 3 exhibit low reflectivity for light of a wavelength of about 550 nm, which has high influence on reflectivity. As described above, the protective members of Examples 1 to 3 are protective members according to an embodiment and include a primer layer. Accordingly, it can be found that the protective member of an embodiment including the primer layer between the hard coating layer and the first low refractive index layer may exhibit excellent reflectivity.

FIG. 9 is a cross-sectional view showing a portion corresponding to line II-II′ in FIG. 3. FIG. 9 may be a cross-sectional view specifically showing a display area DM-DA of a display module DM according to an embodiment.

Referring to FIG. 9, a display panel DP may include a base substrate BS, a circuit layer DP-CL disposed on the base substrate BS, a display element layer DP-EL disposed on the circuit layer DP-CL, and an encapsulation layer TFE covering the display element layer DP-EL. The configuration of the display panel DP illustrated in FIG. 9 is an illustration, and the configuration of the display panel DP is not limited thereto.

The base substrate BS may provide a base surface on which the circuit layer DP-CL is disposed. The base substrate BS may be a flexible substrate capable of bending, folding, rolling, or the like. The base substrate BS may be a glass substrate, a metal substrate, a polymer substrate, or the like. However, embodiments of this disclosure are not limited to the illustrative embodiments depicted in the drawings, and the base substrate BS may include an inorganic layer, an organic layer, or a composite material layer.

The base substrate BS may include a single layer or multiple layers. For example, the base substrate BS may include a first synthetic resin layer, an inorganic layer including multiple layers or a single layer, and a second synthetic resin layer disposed on the inorganic layer including multiple layers or a single layer. Each of the first synthetic resin layer and the second synthetic resin layer may include a polyimide-based resin. In addition, each of the first synthetic resin layer and the second synthetic resin layer may include at least one of an acrylic resin, a methacrylic resin, a polyisoprene-based resin, a vinyl resin, an epoxy-based resin, a urethane-based resin, a cellulose-based resin, a siloxane-based resin, a polyamide-based resin, or a perylene-based resin. In the description, the “˜˜”-based resin means a resin including a functional group of “˜˜.”

The display panel DP may include a transistor TR and a light emitting element ED. The transistor TR and the light emitting element ED may be disposed on the base substrate BS. In FIG. 9, one transistor TR is shown, but the display panel DP may substantially include a plurality of transistors and at least one capacitor for driving the light emitting element ED.

The circuit layer DP-CL may include an insulating layer, a semiconductor pattern, a conductive pattern, a signal line, and the like. For example, the circuit layer DP-CL may include a switching transistor and a driving transistor for driving the light emitting element ED of the display element layer DP-EL.

The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stacked structure of the circuit layer DP-CL shown in FIG. 9 is an illustration, and the stacked structure of the circuit layer DP-CL may be changed depending on the configuration of the display panel DP and the process of the circuit layer DP-CL, or the like.

The shielding electrode BML may be disposed on the base substrate BS. The shielding electrode BML may overlap with the transistor TR. The shielding electrode BML may block light incident on the transistor TR from the lower portion of the display panel DP to protect the transistor TR. The shielding electrode BML may include a conductive material. If a voltage is applied to the shielding electrode BML, the threshold voltage of the transistor TR disposed on the shielding electrode BML may be maintained. However, embodiments of this disclosure are not limited illustrative embodiments, and the shielding electrode BML may be a floating electrode. The shielding electrode BML may be omitted.

The buffer layer BFL may be disposed on the base substrate BS to cover the shielding electrode BML. The buffer layer BFL may include an inorganic layer. The buffer layer BFL may improve the bonding strength between a semiconductor pattern or conductive pattern disposed on the buffer layer BFL and the base substrate BS.

The transistor TR may include a source S1, a channel C1, a drain D1, and a gate G1. The source S1, the channel C1, and the drain D1 of the transistor TR may be formed from the semiconductor pattern. The semiconductor pattern of the transistor TR may include polysilicon, amorphous silicon, or a metal oxide, and any material having semiconductor properties may be applied without limitation and is not limited to any one of them.

The semiconductor pattern may include a plurality of areas that are distinguished by the degree of conductivity. Among the semiconductor patterns, areas doped with a dopant or have a metal oxide that is reduced may have high conductivity and may substantially serve as the source and drain electrodes of the transistor TR. Among the semiconductor patterns, the areas with high conductivity may correspond to the source S1 and drain D1 of the transistor TR. Among the semiconductor patterns, areas that are undoped or doped at a low concentration or have a metal oxide that is not reduced and thus have low conductivity may correspond to the channel C1 (or active) of the transistor TR.

The first insulating layer INS1 may cover the semiconductor pattern of the transistor TR and may be disposed on the buffer layer BFL. The gate G1 of the transistor TR may be disposed on the first insulating layer INS1. On a plane, the gate G1 may overlap the channel C1 of the transistor TR. The gate G1 may function as a mask in the process of doping the semiconductor pattern of the transistor TR.

The second insulating layer INS2 may cover the gate G1 and may be disposed on the first insulating layer INS1. The third insulating layer INS3 may be disposed on the second insulating layer INS2.

The connection electrode CNE may include a first connection electrode CNE1 and a second connection electrode CNE2 for electrically connecting the transistor TR and the light emitting element ED. However, the configuration of the connection electrode CNE for electrically connecting the transistor TR and the light emitting element ED is not limited thereto, and one of the first and second connection electrodes CNE1 and CNE2 may be omitted, or an additional connection electrode may be further included.

The first connection electrode CNE1 may be disposed on the third insulating layer INS3. The first connection electrode CNE1 may be connected to the drain D1 through a first contact hole CH1 penetrating the first to third insulating layers INS1 to INS3. The fourth insulating layer INS4 may cover the first connection electrode CNE1 and may be disposed on the third insulating layer INS3. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 penetrating the fourth and fifth insulating layers INS4 and INS5. The sixth insulating layer INS6 may cover the second connection electrode CNE2 and may be disposed on the fifth insulating layer INS5.

Each of the first to sixth insulating layers INS1 to INS6 may include an inorganic layer or an organic layer. For example, the inorganic layer may include at least one of aluminum oxide, titanium oxide, silicon oxide, silicon oxynitride, zirconium oxide, or hafnium oxide. The organic layer may include at least one of an acrylic resin, a methacrylic resin, a polyisoprene-based resin, a vinyl resin, an epoxy-based resin, a urethane-based resin, a cellulose-based resin, a siloxane-based resin, a polyamide-based resin, and a perylene-based resin.

The display element layer DP-EL may include a pixel defining layer PDL and a light emitting element ED. The light emitting element ED may include a first electrode AE, a hole control layer HCL, an emission layer EML, an electron control layer TCL, and a second electrode CE.

The light emitting element ED may emit light. For example, the light emitting element ED may include an organic light emitting material, an inorganic light emitting material, an organic-inorganic light emitting material, a quantum dot, or a quantum rod. For example, the light emitting element ED may include a micro LED or a nano LED.

The first electrode AE may be disposed on the sixth insulating layer INS6. The first electrode AE may be connected to the second connection electrode CNE2 through a third contact hole CH3 penetrating the sixth insulating layer INS6. The first electrode AE may be electrically connected to the drain D1 of the transistor TR through the first and second connection electrodes CNE1 and CNE2.

The first electrode AE may be formed using a metal material, a metal alloy, or a conductive compound. The first electrode AE may be an anode or a cathode. However, embodiments of this disclosure are not limited illustrative embodiments. In addition, the first electrode AE may be a pixel electrode. The first electrode AE may be a transmissive electrode, a semi-transmissive electrode, or a reflective electrode. The first electrode AE may include at least one selected from Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

When the first electrode AE is a transmissive electrode, the first electrode AE may include a transparent metal oxide. A non-limiting list of metal oxides may include indium tin oxide (ITO), indium zinc oxide (IZO), zinc oxide (ZnO), indium tin zinc oxide (ITZO), or the like. When the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (for example, a mixture of Ag and Mg). Alternatively, the first electrode AE may have a multilayer structure including a reflective film or a semi-transmissive film formed using the above materials and a transparent conductive film formed using indium tin oxide (ITO), indium zinc oxide (IZO), zinc oxide (ZnO), indium tin zinc oxide (ITZO), or the like. For example, the first electrode AE may have a three-layer structure of ITO/Ag/ITO, but embodiments of this disclosure are not limited thereto. In addition, the first electrode AE may include the above-described metal material, a combination of two or more metal materials selected from the above-described metal materials, or an oxide of the above-described metal materials, but embodiments of this disclosure are not limited thereto.

The pixel defining layer PDL may be disposed on the sixth insulating layer INS6. A light emitting opening PX_OP exposing a portion of the first electrode AE may be defined in the pixel defining layer PDL. A portion of the first electrode AE exposed by the light emitting opening PX_OP may be defined as a light emitting area LA.

The display area DM-DA of the display module DM may include a light emitting area LA and a light shielding area NLA. The area where the pixel defining layer PDL is disposed may correspond to the light shielding area NLA. The light shielding area NLA may surround the light emitting area LA within the display area DM-DA.

The hole control layer HCL may be disposed on the first electrode AE and the pixel defining layer PDL. The hole control layer HCL may be provided as a common layer overlapping the light emitting area LA and the light shielding area NLA. The hole control layer HCL may include at least one of a hole transport layer, a hole injection layer, or an electron blocking layer. The hole control layer HCL may include a known hole injection material and/or a known hole transport material.

The emission layer EML may be disposed on the hole control layer HCL. The emission layer EML may be disposed in an area corresponding to the light emitting opening PX_OP. Alternatively, the emission layer EML may be provided as a common layer. The emission layer EML may include an organic light emitting material and/or an inorganic light emitting material. The emission layer EML may emit light of any one of red, green, or blue color. For example, the emission layer EML may emit blue light.

The electron control layer TCL may be disposed on the emission layer EML. The electron control layer TCL may be provided as a common layer overlapping the light emitting area LA and the light shielding area NLA. The electron control layer TCL may include at least one of an electron transport layer, an electron injection layer, and a hole blocking layer. The electron control layer TCL may include a known electron injection material and/or a known electron transport material.

The second electrode CE may be disposed on the electron control layer TCL. The second electrode CE may be provided as a common layer overlapping the light emitting area LA and the light shielding area NLA.

The second electrode CE may be a common electrode. The second electrode CE may be a cathode or an anode, but embodiments of this disclosure are not limited thereto. For example, if the first electrode AE is an anode, the second electrode CE may be a cathode, and if the first electrode AE is a cathode, the second electrode CE may be an anode.

The second electrode CE may be a transmissive electrode, a semi-transmissive electrode, or a reflective electrode. If the second electrode CE is a transmissive electrode, the second electrode CE may be formed using a transparent metal oxide such as indium tin oxide (ITO), indium zinc oxide (IZO), zinc oxide (ZnO), and indium tin zinc oxide (ITZO).

If the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or mixture containing thereof (for example, AgMg, AgYb, or MgYb). Alternatively, the second electrode CE may have a multilayer structure including a reflective film or a semi-transmissive film formed using the above materials and a transparent conductive film formed using indium tin oxide (ITO), indium zinc oxide (IZO), zinc oxide (ZnO), or indium tin zinc oxide (ITZO). For example, the second electrode CE may include the above-described metal material, a combination of two or more metal materials selected from the above-described metal materials, or an oxide of the above-described metal materials.

The encapsulation layer TFE may be disposed on the display element layer DP-EL. The encapsulation layer TFE may be disposed on the second electrode CE to cover the light emitting element ED. The encapsulation layer TFE may protect the display element layer DP-EL from foreign substances such as moisture, oxygen, and/or dust particles. The encapsulation layer TFE may include a plurality of thin films.

The encapsulation layer TFE may include at least one inorganic film. For example, the encapsulation layer TFE may include inorganic films disposed on the second electrode CE and an organic film disposed between the inorganic films. The inorganic film may protect the light emitting element ED from moisture/oxygen, and the organic film may protect the light emitting element ED from foreign substances such as dust particles.

An input sensing part TP may be disposed on the display panel DP. For example, the input sensing part TP may be directly disposed on the encapsulation layer TFE of the display panel DP. Alternatively, an adhesive layer may be disposed between the input sensing part TP and the display panel DP.

The input sensing part TP may include a first sensing insulating layer IL1, a second sensing insulating layer IL2, and a third sensing insulating layer IL3. The input sensing part TP may include at least one conductive layer disposed on the sensing insulating layers. The input sensing part TP may include a first conductive layer CDL1 and a second conductive layer CDL2.

The first sensing insulating layer IL1 may be disposed on the encapsulation layer TFE. The first sensing insulating layer IL1 may include at least one inorganic insulating layer. The first sensing insulating layer IL1 may be in contact with the encapsulation layer TFE. Alternatively, the first sensing insulating layer IL1 may be omitted, and in this case, the first conductive layer CDL1 may be in contact with the encapsulation layer TFE.

The first conductive layer CDL1 may be disposed on the first sensing insulating layer IL1. The first conductive layer CDL1 may include a plurality of first conductive patterns. The plurality of first conductive patterns may be disposed on the first sensing insulating layer IL1. The second sensing insulating layer IL2 may be disposed on the first sensing insulating layer IL1 so as to cover at least a portion of the first conductive layer CDL1.

The second conductive layer CDL2 may be disposed on the second sensing insulating layer IL2. The second conductive layer CDL2 may include a plurality of second conductive patterns. The plurality of second conductive patterns may be disposed on the second sensing insulating layer IL2. Each of the plurality of the second conductive patterns may be connected to the plurality of the first conductive patterns through a contact hole formed in the second sensing insulating layer IL2.

Each of the plurality of first conductive patterns of the first conductive layer CDL1 and the plurality of second conductive patterns of the second conductive layer CDL2 may be disposed corresponding to the light shielding area NLA. Each of the plurality of first conductive patterns of the first conductive layer CDL1 and the plurality of second conductive patterns of the second conductive layer CDL2 may be a mesh pattern.

The third sensing insulating layer IL3 may be disposed on the second sensing insulating layer IL2 and may cover the second conductive layer CDL2. Each of the second sensing insulating layer IL2 and the third sensing insulating layer IL3 may include an inorganic insulating layer or an organic insulating layer.

Each of the first conductive layer CDL1 and the second conductive layer CDL2 may have a single layer structure or a multilayer structure stacked along the third direction DR3. Each of the conductive layers CDL1 and CDL2 with a single layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), and indium tin zinc oxide (ITZO). In addition, the transparent conductive layer may include a conductive polymer such as PEDOT, a metal nanowire, graphene, or the like.

Each of the conductive layers CDL1 and CDL2 with a multilayer structure may include metal layers. The metal layers may have a three layer structure of, for example, titanium (Ti)/aluminum (Al)/titanium (Ti). The conductive layers CDL1 and CDL2 with a multilayer structure may include at least one metal layer and at least one transparent conductive layer.

FIG. 10 is a block diagram of an electronic apparatus according to an embodiment. The electronic apparatus EA may further include at least one of a processor PR, a memory MR, or a power module PM. Referring to FIG. 10, the electronic apparatus EA according to an embodiment may include a display module DM, a processor PR, a memory MR, and a power module PM.

The processor PR may include at least one of a central processing unit CPU, an application processor AP, a graphic processing unit GPU, a communication processor CP, an image signal processor ISP, or a controller.

In the memory MR, data information required for the operation of the processor PR or the display module DM may be stored. If the processor PR runs an application stored in the memory MR, an image data signal and/or an input control signal are transmitted to the display module DM, and the display module DM may process the provided signal and output image information through a display screen.

The power module PM may include a power supply modules such as a power adapter and a battery device, and a power conversion module that converts power supplied by the power supply module to generate power necessary for the operation of the electronic apparatus EA.

At least one of each configuration of the above-described electronic apparatus EA may be included in the display device according to the above-described embodiments. In addition, some of the individual modules included in functionally one module are included in the display device and some may be provided separately from the display device. For example, the display device includes the display module DM, and the processor PR, memory (MR), and power module PM may be provided in the form of another device, not the display device in the electronic apparatus EA.

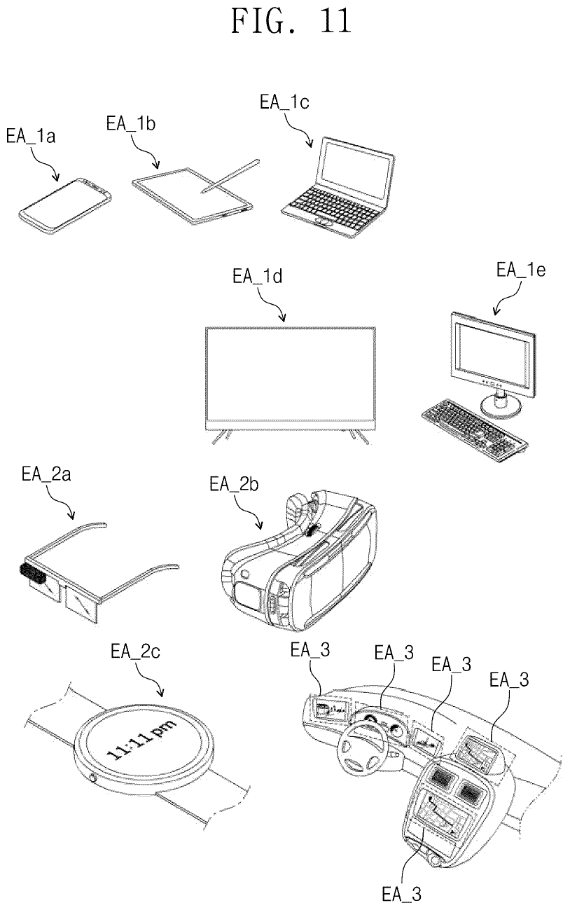

FIG. 11 illustrates schematic diagrams of electronic apparatuses according to various embodiments. Referring to FIG. 11, various electronic apparatuses with display devices according to embodiments may include not only electronic apparatuses for displaying images such as smartphone EA_1a, tablet PC EA_1b, laptop EA_1c, TV EA_1d, and a monitor for desks, EA_1e, but also wearable electronic apparatuses such as smart glasses EA_2a, head mount display EA_2b, and smart watch EA_2c, and electronic apparatuses for a vehicle EA_3, which includes display modules such as car instrument panel, center console, a center information display (CID) disposed on a dashboard and a room mirror display. The foregoing are illustrative.

An electronic apparatus of an embodiment may include a display device. The display device may include a foldable display panel and a protective member disposed on the display panel. The protective member may include a primer layer disposed between a hard coating layer and a first low refractive index layer. The primer layer may include a titanium alkoxide oligomer and a polar compound, wherein the number of carbon atoms in the titanium alkoxide oligomer may be 96 to 320. Accordingly, the protective member including the primer layer may exhibit excellent reflectivity while preventing cracks from occurring during repeated folding and unfolding. The display device including the protective member and the electronic apparatus including the same may exhibit excellent display quality and excellent folding reliability.

A display device and an electronic apparatus including the display device of an embodiment includes a primer layer including a metal compound and a polar compound, and may show excellent display quality and excellent folding reliability.

Although the embodiments have been described above with reference to specific embodiments thereof, it will be understood that those skilled in the art or having ordinary knowledge in the art can modify and change the embodiments of this disclosure in various ways without departing from the spirit and technical scope of the disclosure.

Therefore, the technical scope should not be limited to the contents described in the detailed description of the specification, but should be determined by the claims.

What is claimed is:

1. A display device comprising a display panel foldable based on at least one folding axis, and a protective member disposed on the display panel,
wherein the protective member comprises:
a base layer;
a hard coating layer disposed on the base layer;
a first low refractive index layer disposed on the hard coating layer; and
a primer layer comprising a metal compound and a polar compound, the primer layer being disposed between the hard coating layer and the first low refractive index layer,
the metal compound comprises at least one of a titanium alkoxide oligomer, a zirconium alkoxide oligomer, or a zirconium chelate compound, and
a number of carbon atoms in the titanium alkoxide oligomer is 96 to 320.

2. The display device of claim 1,
wherein the titanium alkoxide oligomer comprises at least one of a first moiety represented by the following Formula 1 or a second moiety represented by the following Formula 2,
the zirconium alkoxide oligomer comprises at least one of a third moiety represented by the following Formula 3 or a fourth moiety represented by the following Formula 4, and
the zirconium chelate compound comprises zirconium acetylacetonate:

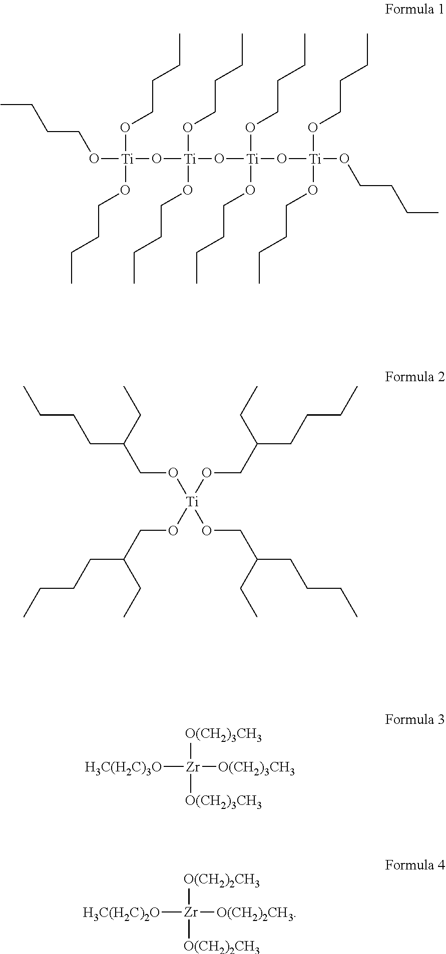

3. The display device of claim 1, wherein the polar compound comprises an amine group.

4. The display device of claim 1, wherein the polar compound comprises at least one of 2-(2-aminoethoxy)ethylamine, 4-(2-aminoethoxy)phenol, or triethanolamine.

5. The display device of claim 1, wherein a refractive index of the primer layer is higher than a refractive index of the first low refractive index layer.

6. The display device of claim 1, wherein a refractive index of the primer layer is about 1.62 to about 1.91.

7. The display device of claim 1, wherein a thickness of the primer layer is smaller than a thickness of the hard coating layer.

8. The display device of claim 1, wherein the primer layer is disposed directly between the hard coating layer and the first low refractive index layer.

9. The display device of claim 1,
wherein the first low refractive index layer comprises at least one of silicon dioxide (SiO₂) or a first substitutional solid solution, and
the first substitutional solid solution comprises silicon atoms, aluminum atoms and oxygen atoms.

10. The display device of claim 1, wherein the protective member further comprises a high refractive index layer disposed on the first low refractive index layer, and a second low refractive index layer disposed on the high refractive index layer.

11. The display device of claim 10,
wherein the high refractive index layer comprises a second substitutional solid solution comprising niobium atoms, titanium atoms, and oxygen atoms, and
the second low refractive index layer comprises silicon dioxide.

12. The display device of claim 1, wherein the hard coating layer comprises a silsesquioxane resin.

13. The display device of claim 12, wherein the silsesquioxane resin comprises at least one of a random structure, a partial cage structure, a ladder structure or a cage structure.

14. The display device of claim 1, wherein the base layer comprises at least one of polyethylene terephthalate, polyimide, polyacrylate, polymethyl acrylate, polymethyl methacrylate, polycarbonate, polyethylene naphthalate, polyvinylidene chloride, polyvinylidene difluoride, polystyrene, and an ethylene vinyl alcohol copolymer.

15. An electronic apparatus comprising a display device providing images,
wherein the display device comprises a display panel foldable based on at least one folding axis, and a protective member disposed on the display panel,
the protective member comprises:
a base layer;
a hard coating layer disposed on the base layer;
a first low refractive index layer disposed on the hard coating layer; and
a primer layer comprising a metal compound and a polar compound, the primer layer being disposed between the hard coating layer and the first low refractive index layer,
the metal compound comprises at least one of a titanium alkoxide oligomer, a zirconium alkoxide oligomer, or a zirconium chelate compound, and
a number of carbon atoms in the titanium alkoxide oligomer is 96 to 320.

16. The electronic apparatus of claim 15,
wherein the titanium alkoxide oligomer comprises at least one of a first moiety represented by the following Formula 1 or a second moiety represented by the following Formula 2,
the zirconium alkoxide oligomer comprises at least one of a third moiety represented by the following Formula 3 or a fourth moiety represented by the following Formula 4, and
the zirconium chelate compound comprises zirconium acetylacetonate:

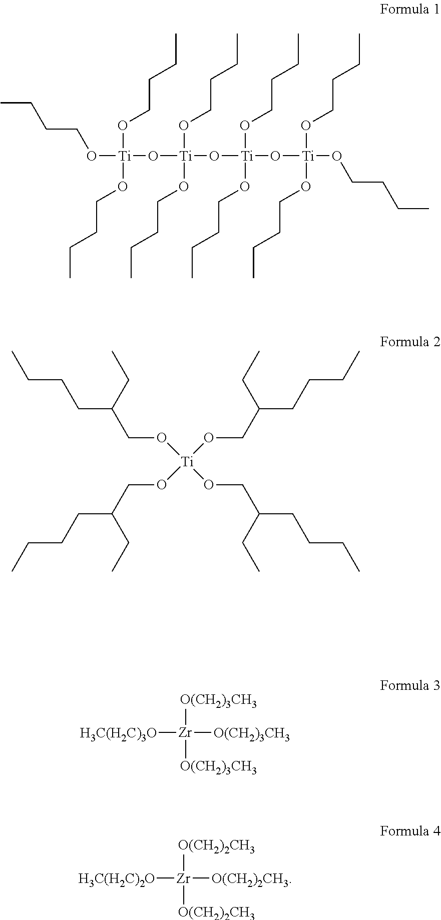

17. The electronic apparatus of claim 15, wherein the polar compound comprises at least one of 2-(2-aminoethoxy)ethylamine, 4-(2-aminoethoxy)phenol, or triethanolamine.

18. The electronic apparatus of claim 15,
wherein a refractive index of the primer layer is higher than a refractive index of the first low refractive index layer, and
a refractive index of the primer layer is about 1.62 to about 1.91.

19. The electronic apparatus of claim 15,
wherein the protective member further comprises a high refractive index layer disposed on the first low refractive index layer, and a second low refractive index layer disposed on the high refractive index layer, and
the high refractive index layer comprises a substitutional solid solution comprising niobium atoms, titanium atoms, and oxygen atoms.

20. The electronic apparatus of claim 15, further comprising at least one of a processor, a power module, or a memory.
